(19) United States
(12) Patent Application Publication
(10) Pub. No.: US 2024/0405149 A1
(43) Pub. Date: Dec. 5, 2024

(54) LIGHT RECEIVING DEVICE, DISTANCE MEASUREMENT APPARATUS, DISTANCE MEASUREMENT MODULE, ELECTRONIC APPARATUS, AND MANUFACTURING METHOD FOR A LIGHT RECEIVING DEVICE

(71) Applicant: SONY SEMICONDUCTOR SOLUTIONS CORPORATION, KANAGAWA (JP)

(72) Inventors: HIIZU OHTORII, KANAGAWA (JP); YUSUKE OYAMA, KANAGAWA (JP); TAKESHI KODAMA, KANAGAWA (JP); JUN SUZUKI, KANAGAWA (JP); KEN KIKUCHI, KANAGAWA (JP); NOBUTAKE IWASE, KANAGAWA (JP); KENJI SATO, KANAGAWA (JP)

(21) Appl. No.: 18/694,540

(22) PCT Filed: Sep. 14, 2022
(86) PCT No.: PCT/JP2022/034427

§ 371 Date: Mar. 22, 2024

(30) Foreign Application Priority Data
Oct. 4, 2021 (JP) 2021-163350

(51) Int. Cl. H01L 31/167; G01S 17/08; H01L 31/02; H01L 31/0203; H01L 31/18

(52) U.S. Cl. CPC H01L 31/167; G01S 17/08; H01L 31/02005; H01L 31/0203; H01L 31/18

(57) ABSTRACT

To improve the measurement accuracy. The present technology provides a light receiving device (1) including: a light transmitting part (11) that transmits emitted light emitted from a light emitting device; a light receiver (12) that receives incident light from outside; and a semiconductor substrate (13), in which a non-sensitive region (14) that does not sense light is formed between the light transmitting part (11) and the light receiver (12). Moreover, the present technology provides a manufacturing method for a light receiving device (1) including: stacking a light receiver (12) on one surface of a semiconductor substrate (13); etching a side on which the light receiver (12) is disposed into a ring shape; fixing the semiconductor substrate (13) to a permanent fixing substrate; etching an outer periphery and substantially a center portion of the light receiver (12); and removing the semiconductor substrate (13) from the permanent fixing substrate by laser lift off.

### TECHNICAL FIELD

The present technology relates to a light receiving device, a distance measurement apparatus, a distance measurement module, an electronic apparatus, and a manufacturing method for a light receiving device.

### BACKGROUND ART

Conventionally, a technology of calculating a distance to an object, a shape of the object, and the like by measuring scattered light or reflected light of light radiated to the object from a light source is used in a LiDAR scanner, a ToF sensor, or the like.

For example, Patent Literature 1 has disclosed “an optical coupling device including: a light receiving and emitting device including a light emitter configured to emit emitted light and a light receiver configured to receive incident light from the outside of the optical coupling device, in which the light receiver includes a light transmitting part through which the emitted light passes, which is arranged on an optical axis of the incident light; and an optical device configured to refract light of the incident light so as to be apart from the optical axis, in which the light of the incident light is around the optical axis, and cause the refracted light of the incident light to enter the light receiver.”

### CITATION LIST

### Patent Literature

Patent Literature 1: WO 2018/079091

### DISCLOSURE OF INVENTION

### Technical Problem

Patent Literature 1 has not disclosed a semiconductor configuration such as a P-type semiconductor or an N-type semiconductor. Moreover, the inventors have found that when the emitted light from the light source enters the light receiver, this emitted light becomes noise and it lowers the measurement accuracy.

In view of this, it is a main object of the present technology to provide a light receiving device, a distance measurement apparatus, a distance measurement module, an electronic apparatus, and a manufacturing method for a light receiving device that improve the measurement accuracy.

### Solution to Problem

The present technology provides a light receiving device including: a light transmitting part that transmits emitted light emitted from a light emitting device; a light receiver that receives incident light from outside; and a semiconductor substrate, in which a non-sensitive region that does not sense light is formed between the light transmitting part and the light receiver.

The non-sensitive region may include an insulating film. The non-sensitive region may include a light shielding film.

The non-sensitive region may include an insulating film and a light shielding film.

A solder bump may be formed on the semiconductor substrate.

A light shielding layer may be formed on an opposite side of the light receiver side.

The light transmitting part may be formed so that a diameter on an opposite side of the light receiver side in a side cross-sectional view is smaller than a diameter on the light receiver side.

The light transmitting part may be formed in a stepped-shape in a side cross-sectional view and has a top portion.

In side cross-sectional view, a first straight line connecting substantially a center of a first aperture positioned on an opposite side of the light receiver side or the light emitting device and the top portion may be positioned more inward than a second straight line connecting substantially a center of the first aperture or the light emitting device and an end portion of a second aperture positioned on the light receiver side.

The light transmitting part may be formed in a taper shape in a side cross-sectional view.

The light transmitting part may be formed of a transparent material which is transparent or translucent.

The light receiver may be formed in a ring shape in a plan view.

The light receiver may include a plurality of regions in a plan view.

The light receiver may include four or more regions in a plan view.

The light receiver may include eight or more regions in a plan view.

The light receiver may be disposed so that a plurality of regions is vertically and horizontally arranged in a plan view.

Moreover, the present technology provides a distance measurement apparatus including: the above-mentioned light receiving device; and a light emitting device that emits the emitted light.

Moreover, the present technology provides a distance measurement module including the above-mentioned distance measurement apparatus.

Moreover, the present technology provides an electronic apparatus including the above-mentioned distance measurement apparatus.

Moreover, the present technology provides a manufacturing method for a light receiving device including: stacking a light receiver on one surface of a semiconductor substrate; etching a side on which the light receiver is disposed into a ring shape; fixing the semiconductor substrate to a permanent fixing substrate; etching an outer periphery and substantially a center portion of the light receiver; and removing the semiconductor substrate from the permanent fixing substrate by laser lift off.

In accordance with the present technology, it is possible to provide a light receiving device, a distance measurement apparatus, a distance measurement module, an electronic apparatus, and a manufacturing method for a light receiving device that improve the measurement accuracy. It should be noted that the effects set forth herein are not necessarily limited and may be any one of the effects described in the present disclosure.

### BRIEF DESCRIPTION OF DRAWINGS

FIG. 1 A plan view and a side cross-sectional view showing a configuration example of a light receiving device 1 according to an embodiment of the present technology.

FIG. 2 A plan view and a side cross-sectional view showing a configuration example of a light receiving device 1 according to an embodiment of the present technology.

FIG. 3 A plan view and a side cross-sectional view showing a configuration example of a light receiving device 1 according to an embodiment of the present technology.

FIG. 4 A plan view and a side cross-sectional view showing a configuration example of a light receiving device 1 according to an embodiment of the present technology.

FIG. 5 A plan view and a side cross-sectional view showing a configuration example of a light receiving device 1 according to an embodiment of the present technology.

FIG. 6 A plan view and a side cross-sectional view showing a configuration example of a light receiving device 1 according to an embodiment of the present technology.

FIG. 7 A plan view and a side cross-sectional view showing a configuration example of a light receiving device 1 according to an embodiment of the present technology.

FIG. 8 Side cross-sectional views showing configuration examples of light receiving devices 1 according to embodiments of the present technology.

FIG. 9 A side cross-sectional view showing a configuration example of a light receiving device 1 according to an embodiment of the present technology.

FIG. 10 A side cross-sectional view showing a configuration example of a light receiving device 1 according to an embodiment of the present technology.

FIG. 11 A side cross-sectional view showing a configuration example of a light receiving device 1 according to an embodiment of the present technology.

FIG. 12 A plan view and a side cross-sectional view showing a configuration example of a light receiving device 1 according to an embodiment of the present technology.

FIG. 13 A side cross-sectional view showing a configuration example of a light receiving device 1 according to an embodiment of the present technology.

FIG. 14 A plan view showing a configuration example of a light receiving device 1 according to an embodiment of the present technology.

FIG. 15 A plan view showing a configuration example of a light receiving device 1 according to an embodiment of the present technology.

FIG. 16 A plan view showing a configuration example of a light receiving device 1 according to an embodiment of the present technology.

FIG. 17 A plan view showing a configuration example of a light receiving device 1 according to an embodiment of the present technology.

FIG. 18 A side cross-sectional view showing a configuration example of a distance measurement apparatus 10 according to an embodiment of the present technology.

FIG. 19 A side cross-sectional view showing a configuration example of a distance measurement apparatus 10 according to an embodiment of the present technology.

FIG. 20 A perspective view, a plan view, and a side cross-sectional view showing a configuration example of a distance measurement module 100 according to an embodiment of the present technology.

FIG. 21 A perspective view showing a configuration example of an electronic apparatus 200 according to an embodiment of the present technology.

FIG. 22 A side cross-sectional view showing a configuration example of a light receiving device 1 according to a comparative example of the present technology.

FIG. 23 A side cross-sectional view showing the configuration example of the light receiving device 1 according to the comparative example of the present technology.

FIG. 24 A side cross-sectional view showing a configuration example of a light receiving device 1 according to a comparative example of the present technology.

FIG. 25 A side cross-sectional view showing the configuration example of the light receiving device 1 according to the comparative example of the present technology.

FIG. 26 A side cross-sectional view showing the configuration example of the light receiving device 1 according to the comparative example of the present technology.

FIG. 27 A side cross-sectional view showing a configuration example of a light receiving device 1 according to a comparative example of the present technology.

FIG. 28 A side cross-sectional view showing the configuration example of the light receiving device 1 according to the comparative example of the present technology.

FIG. 29 A side cross-sectional view showing the configuration example of the light receiving device 1 according to the comparative example of the present technology.

FIG. 30 A side cross-sectional view showing the configuration example of the light receiving device 1 according to the comparative example of the present technology.

FIG. 31 A side cross-sectional view showing a configuration example of a light receiving device 1 according to an embodiment of the present technology.

FIG. 32 A side cross-sectional view showing the configuration example of the light receiving device 1 according to the embodiment of the present technology.

FIG. 33 A side cross-sectional view showing the configuration example of the light receiving device 1 according to the embodiment of the present technology.

FIG. 34 A side cross-sectional view showing the configuration example of the light receiving device 1 according to the embodiment of the present technology.

FIG. 35 A side cross-sectional view showing the configuration example of the light receiving device 1 according to the embodiment of the present technology.

FIG. 36 A side cross-sectional view showing the configuration example of the light receiving device 1 according to the embodiment of the present technology.

FIG. 37 A side cross-sectional view showing the configuration example of the light receiving device 1 according to the embodiment of the present technology.

FIG. 38 A side cross-sectional view showing a configuration example of a light receiving and emitting device 3 according to an embodiment of the present technology.

FIG. 39 A side cross-sectional view showing a configuration example of a light receiving and emitting device according to a comparative example of the present technology.

FIG. 40 A plan view showing a configuration example of a light receiving and emitting device 3 according to an embodiment of the present technology.

FIG. 41 A plan view showing a configuration example of a light receiving and emitting device 3 according to an embodiment of the present technology.

FIG. 42 A plan view showing a configuration example of a light receiving and emitting device 3 according to an embodiment of the present technology.

FIG. 43 A diagram of assistance in explaining an example of operation timings of a light receiving device 1 and a light emitting device 2 according to an embodiment of the present technology.

FIG. 44 A side cross-sectional view showing a configuration example of a light receiving and emitting device 3 according to an embodiment of the present technology.

### MODE(S) FOR CARRYING OUT THE INVENTION

Hereinafter, favorable modes for carrying out the present invention will be described with reference to the drawings. It should be noted that embodiments described below show examples of typical embodiments of the present invention, and the scope of the present invention should not be limited by them. Moreover, some of examples described below and modified examples thereof can be combined for the present invention.

In the descriptions of the embodiments described below, configurations will be described sometimes by terms with “substantially”, e.g., “substantially parallel” or “substantially orthogonal.” For example, “substantially parallel” means not only “completely parallel”, but also “substantially parallel”, i.e., it means that it also includes a state deviated from the completely parallel state by, for example, about several %. The same applies to other terms with “substantially.” Moreover, the respective figures are schematic views and are not necessarily those precisely depicted.

In the drawings, the term “upper” means an upper direction or upper side in the figure, the term “lower” means a lower direction or lower side in the figure, the term “left” means a left-hand direction or left-hand side in the figure, and the term “right” means a right-hand direction or right-hand side in the figure unless otherwise stated herein. Moreover, in the drawings, identical or equivalent elements or members will be denoted by the same reference signs and duplicate descriptions will be omitted.

The descriptions will be given in the following order.
1. First Embodiment (Example 1 of Light Receiving Device)
2. Second Embodiment (Example 2 of Light Receiving Device)
3. Third Embodiment (Example 3 of Light Receiving Device)
4. Fourth Embodiment (Example 4 of Light Receiving Device)
5. Fifth Embodiment (Example 5 of Light Receiving Device)
6. Sixth Embodiment (Example 6 of Light Receiving Device)
7. Seventh Embodiment (Example 7 of Light Receiving Device)
8. Eighth Embodiment (Example 8 of Light Receiving Device)
9. Ninth Embodiment (Example 9 of Light Receiving Device)
10. Tenth Embodiment (Example 10 of Light Receiving Device)
11. Eleventh Embodiment (Example 11 of Light Receiving Device)
12. Twelfth Embodiment (Example 12 of Light Receiving Device)
13. Thirteenth Embodiment (Example 13 of Light Receiving Device)
14. Fourteenth Embodiment (Example of Distance Measurement Apparatus)
15. Fifteenth Embodiment (Example 1 of Light Receiving and Emitting Device)
16. Sixteenth Embodiment (Example 2 of Light Receiving and Emitting Device)
17. Seventeenth Embodiment (Example of Distance Measurement Module)
18. Eighteenth Embodiment (Example of Electronic Apparatus)
19. Nineteenth Embodiment (Example of Manufacturing Method for Light Receiving Device)

### 1. FIRST EMBODIMENT (EXAMPLE 1 OF LIGHT RECEIVING DEVICE)

A light receiving device according to an embodiment of the present technology is a light receiving device including a light transmitting part that transmits emitted light emitted from a light emitting device, a light receiver that receives incident light from outside, and a semiconductor substrate, in which a non-sensitive region that does not sense light is formed between the light transmitting part and the light receiver.

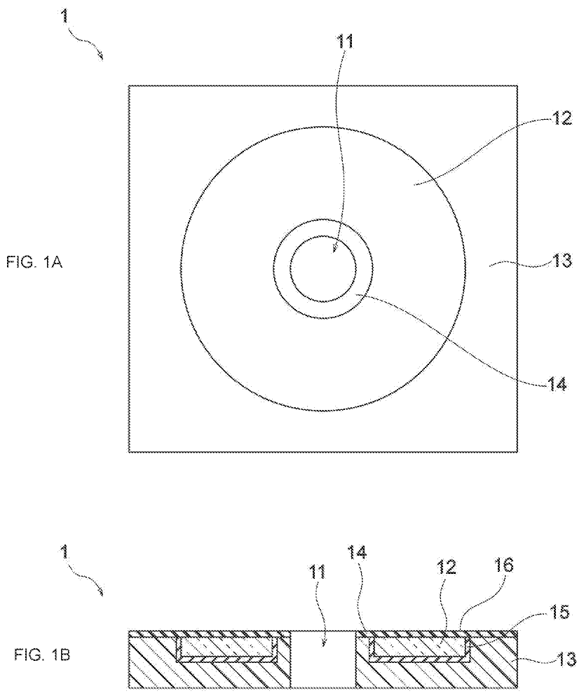

The light receiving device according to the embodiment of the present technology will be described with reference to FIG. 1. A of FIG. 1 is a plan view showing a configuration example of a light receiving device 1 according to the embodiment of the present technology. B of FIG. 1 is a side cross-sectional view showing the configuration example of the light receiving device 1 according to the embodiment of the present technology.

As shown in FIG. 1, the light receiving device 1 according to the embodiment of the present technology includes a light transmitting part 11 that transmits emitted light emitted from a light emitting device, a light receiver 12 that receives incident light from outside, and a semiconductor substrate 13. A non-sensitive region 14 that does not sense light is formed between the light transmitting part 11 and the light receiver 12.

The light receiver 12 is disposed in one surface of the semiconductor substrate 13. The light receiver 12 is a P-type semiconductor. The semiconductor substrate 13 is an N-type semiconductor. A first insulating layer 15 is disposed between the light receiver 12 and the semiconductor substrate 13. The first insulating layer 15 is an I-type semiconductor. The light receiving device 1 is generally called PIN diode. It should be noted that the light receiving device 1 may be a PN semiconductor without the I-type semiconductor.

The light receiver 12 formed in a ring shape in a plan view. It should be noted that the shape of the light receiver 12 is not limited thereto. The shape of the light receiver 12 may be, for example, an elliptical ring shape, a rectangular shape, or the like in a plan view. The rectangular shape includes, for example, a square, a rectangle, a square with rounded corners, a rectangle with rounded corners, and the like. In addition, the shape of the light receiver 12 may be a polygonal shape such as a triangle, a pentagon, or a hexagon.

A second insulating layer 16 is disposed outside the light receiver 12. That is, the second insulating layer 16, the light receiver 12, and the semiconductor substrate 13 are stacked in the stated order. Accordingly, it is possible to prevent moisture, impurities, etc. from adhering to the light receiver 12. The second insulating layer 16 includes, for example, silicon nitride and the like.

The light transmitting part 11 transmits emitted light from a light emitting device (not shown). The light transmitting part 11 may be, for example, a through-hole or the like. In B of FIG. 1, the light emitting device can be disposed just below the light transmitting part 11. The emitted light emitted from the light emitting device passes through the light transmitting part 11 and is radiated to an object. The light receiver 12 receives incident light such as scattered light or reflected light caused when light is radiated to the object. Accordingly, for example, a distance to the object and the like can be measured.

At this time, when the emitted light from the light emitting device passes through the light transmitting part 11, the emitted light sometimes enters the light receiver 12. The amount of light of the emitted light from the light emitting device is several tens of times as large as the amount of light of the incident light from the object. Therefore, there is a problem in that when the emitted light from the light emitting device enters the light receiver 12, the emitted light becomes noise and it lowers the measurement accuracy.

Therefore, the non-sensitive region 14 that does not sense light is formed between the light transmitting part 11 and the light receiver 12. Accordingly, it is possible to prevent the emitted light from the light emitting device from entering the light receiver 12. As a result, it is possible to prevent lowering of the measurement accuracy.

Although the embodiment of the non-sensitive region 14 is not particularly limited, for example, as shown in B of FIG. 1, a portion of the semiconductor substrate 13 may be formed as the non-sensitive region 14.

It should be noted that the light transmitting part 11 may be formed of a transparent material which is transparent or translucent. That is, the light transmitting part 11 may be one obtained by filling a through-hole with a transparent material which is transparent or translucent. The transparent material may have transmittance of, for example, 50% or more. For example, a polyimide resin, an acrylic resin, a photoresist resin, or the like can be used as the transparent material.

The above contents where the light receiving device according to the first embodiment of the present technology has been described can be applied to other embodiments of the present technology if there are no particular technical contradictions.

### 2. SECOND EMBODIMENT (EXAMPLE 2 OF LIGHT RECEIVING DEVICE)

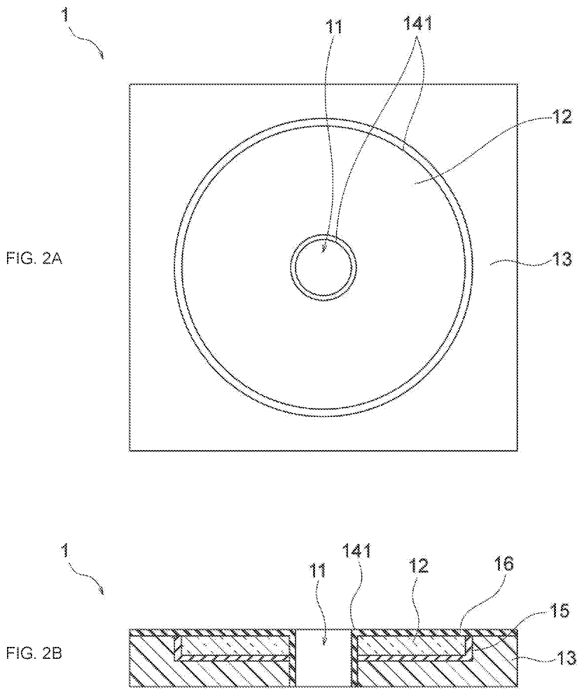

The non-sensitive region may include an insulating film. It will be described with reference to FIG. 2. A of FIG. 2 is a plan view showing a configuration example of a light receiving device 1 according to an embodiment of the present technology. B of FIG. 2 is a side cross-sectional view showing the configuration example of the light receiving device 1 according to the embodiment of the present technology.

As shown in FIG. 2, in the light receiving device 1 according to the embodiment of the present technology, the non-sensitive region 14 includes an insulating film 141. Accordingly, it is possible to prevent the emitted light from the light emitting device from entering the light receiver 12. As a result, it is possible to prevent lowering of the measurement accuracy.

The insulating film 141 may be the same material as the first insulating layer 15 and/or the second insulating layer 16. This insulating film 141 can be, for example, a nitride film, an oxide film, or the like.

The above contents where the light receiving device according to the second embodiment of the present technology has been described can be applied to other embodiments of the present technology if there are no particular technical contradictions.

### 3. THIRD EMBODIMENT (EXAMPLE 3 OF LIGHT RECEIVING DEVICE)

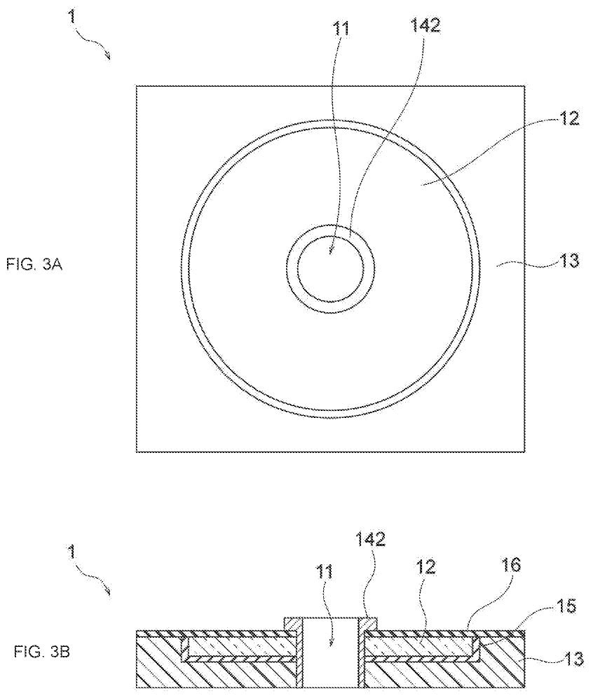

The above-mentioned non-sensitive region may include a light shielding film. It will be described with reference to FIG. 3. A of FIG. 3 is a plan view showing a configuration example of a light receiving device 1 according to an embodiment of the present technology. B of FIG. 3 is a side cross-sectional view showing the configuration example of the light receiving device 1 according to the embodiment of the present technology.

As shown in FIG. 3, in the light receiving device 1 according to the embodiment of the present technology, the non-sensitive region 14 includes a light shielding film 142. The light shielding layer 17 includes, for example, metals such as aluminum and gold.

A portion of the light shielding film 142, which is disposed on a light receiving side, projects outwards in a plan view. Accordingly, during the manufacture of the light receiving device 1, the light shielding film 142 can be reliably formed even if the position is slightly deviated.

The above contents where the light receiving device according to the third embodiment of the present technology has been described can be applied to other embodiments of the present technology if there are no particular technical contradictions.

### 4. FOURTH EMBODIMENT (EXAMPLE 4 OF LIGHT RECEIVING DEVICE)

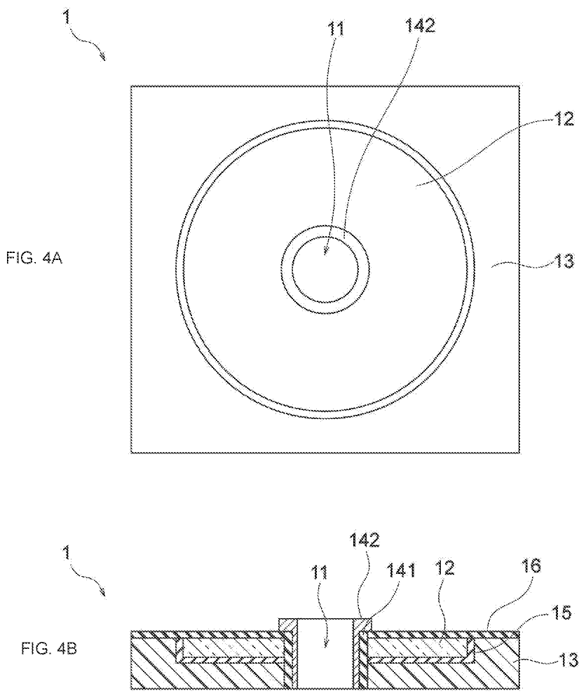

The non-sensitive region may include an insulating film and a light shielding film. It will be described with reference to FIG. 4. A of FIG. 4 is a plan view showing a configuration example of a light receiving device 1 according to an embodiment of the present technology. B of FIG. 4 is a side cross-sectional view showing the configuration example of the light receiving device 1 according to the embodiment of the present technology.

As shown in FIG. 4, in the light receiving device 1 according to the embodiment of the present technology, the non-sensitive region 14 includes an insulating film 141 and a light shielding film 142. A portion of the light shielding film 142, which is disposed on a light receiving side, projects outwards in a plan view. Accordingly, during the manufacture of the light receiving device 1, the light shielding film 142 can be reliably formed even if the position is slightly deviated.

It should be noted that although in B of FIG. 4, the light transmitting part 11, the insulating film 141, and the light shielding film 142 are disposed in the stated order, the present technology is not limited to this order. Although it is not shown in the figure, for example, the light transmitting part 11, the light shielding film 142, and the insulating film 141 may be disposed in the stated order.

The above contents where the light receiving device according to the fourth embodiment of the present technology has been described can be applied to other embodiments of the present technology if there are no particular technical contradictions.

### 5. FIFTH EMBODIMENT (EXAMPLE 5 OF LIGHT RECEIVING DEVICE)

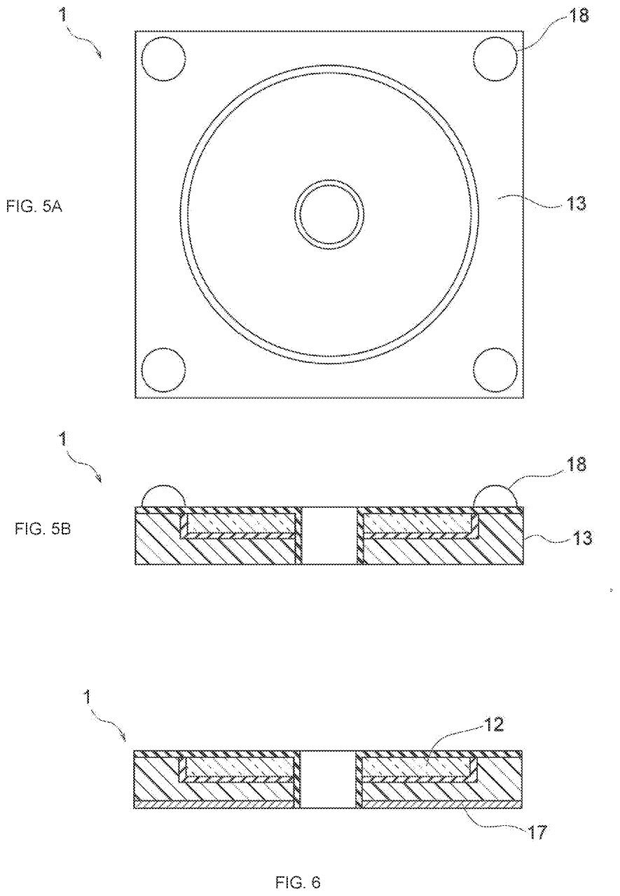

Solder bumps may be formed on the semiconductor substrate. It will be described with reference to FIG. 5. A of FIG. 5 is a plan view showing a configuration example of a light receiving device 1 according to an embodiment of the present technology. B of FIG. 5 is a side cross-sectional view showing the configuration example of the light receiving device 1 according to the embodiment of the present technology.

As shown in FIG. 5, solder bumps 18 are formed on the semiconductor substrate 13. The solder bumps 18 may be formed on a light receiver side or may be formed on an opposite side of the light receiver side. The solder bumps 18 electrically connect the light receiving device 1 to a circuit board (not shown). The solder bumps 18 can be formed by mounting solder balls on the semiconductor substrate 13 and fusing them. The solder balls are made of, for example, gold-tin (AuSn), tin-silver (SnAg), a tin/silver/copper (SnAgCu) alloy, or the like.

In the manufacturing process for the light receiving device 1, self-aligning mounting using the surface tension of the solder is performed due to the formed solder bumps 18, such that the positioning can be easily and reliably achieved in the order of μm.

It is favorable that two or more solder bumps 18 are formed for the single light receiving device 1. Although the solder bumps 18 are formed at the four corners of the semiconductor substrate 13 in A of FIG. 5, the solder bumps 18 may be formed at any two of the four corners. Accordingly, electrical signals of the anode and the cathode can be acquired.

It is more favorable that three or more solder bumps 18 are formed for the single light receiving device 1. Although the solder bumps 18 are formed at the four corners of the semiconductor substrate 13 in A of FIG. 5, the solder bumps 18 may be formed at any three of the four corners. Accordingly, the positioning in the upper and lower directions and the left and right directions in A of FIG. 5 can be easily and reliably achieved.

The above contents where the light receiving device according to the fifth embodiment of the present technology has been described can be applied to other embodiments of the present technology if there are no particular technical contradictions.

### 6. SIXTH EMBODIMENT (EXAMPLE 6 OF LIGHT RECEIVING DEVICE)

A light shielding layer may be formed on the opposite side of the light receiver side. It will be described with reference to FIG. 6. A of FIG. 6 is a plan view showing a configuration example of a light receiving device 1 according to an embodiment of the present technology. B of FIG. 6 is a side cross-sectional view showing the configuration example of the light receiving device 1 according to the embodiment of the present technology.

As shown in FIG. 6, a light shielding layer 17 is formed on the opposite side of the light receiver 12 side. The light shielding layer 17 includes, for example, metals such as aluminum and gold. The light shielding layer 17 may have a thickness of, for example, 1 μm or less.

In a case where the length of the light receiving device 1 in the direction of the thickness is small, for example, approximately 20 to 30 μm, emitted light with a predetermined wavelength from the light emitting device (not shown) disposed on the opposite side of the light receiver 12 side sometimes passes through the semiconductor substrate 13 and enters the light receiver 12. The formed light shielding layer 17 can prevent the emitted light from the light emitting device from entering the light receiver 12. As a result, it is possible to prevent lowering of the measurement accuracy.

The above contents where the light receiving device according to the sixth embodiment of the present technology has been described can be applied to other embodiments of the present technology if there are no particular technical contradictions.

### 7. SEVENTH EMBODIMENT (EXAMPLE 7 OF LIGHT RECEIVING DEVICE)

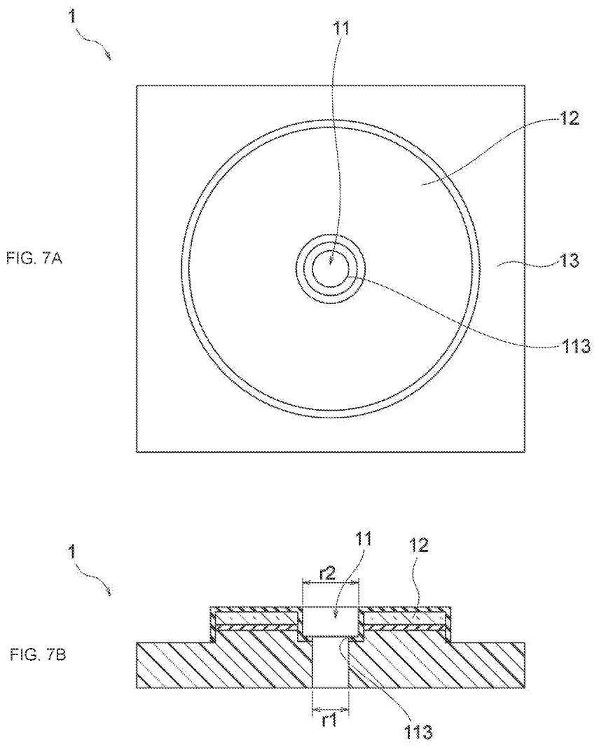

The light transmitting part may be formed so that a diameter on the opposite side of the light receiver side in a side cross-sectional view is smaller than a diameter on the light receiver side. It will be described with reference to FIG. 7. A of FIG. 7 is a plan view showing a configuration example of a light receiving device 1 according to an embodiment of the present technology. B of FIG. 7 is a side cross-sectional view showing the configuration example of the light receiving device 1 according to the embodiment of the present technology.

As shown in B of FIG. 7, the light transmitting part 11 is formed so that a diameter r1 on the opposite side of the light receiver 12 side in a side cross-sectional view is smaller than a diameter r2 on the light receiver 12 side. Accordingly, it is possible to prevent emitted light from the light emitting device (not shown) disposed on the opposite side of the light receiver 12 side from entering the light receiver 12.

The reason therefor will be described. It is ideal that the emitted light from the light emitting device is parallel light. However, even a light emitting device with significantly high directivity can generate emitted light slightly widened with several degrees of gradient. Therefore, the emitted light from the light emitting device may directly enter the light receiver 12.

However, since the diameter r2 on the opposite side of the light receiver 12 side, that is, the light emitting device side is smaller, the slightly widened emitted light hits the inner wall of the light transmitting part 11 so that its spread is cancelled. As a result, it is possible to prevent the emitted light from the light emitting device from entering the light receiver 12.

In addition, the light transmitting part 11 is formed in a stepped-shape in a side cross-sectional view and has a top portion 113. Accordingly, the slightly widened emitted light hits the top portion 113 or the like, such that its spread is canceled. As a result, it is possible to prevent the emitted light from the light emitting device from entering the light receiver 12.

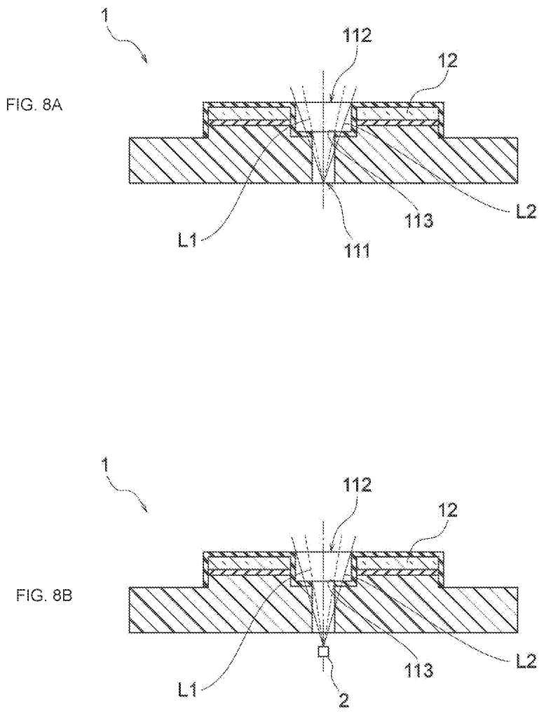

In particular, it is favorable that in a side cross-sectional view, a first straight line connecting substantially the center of a first aperture positioned on the opposite side of the light receiver side or the light emitting device and the top portion is positioned more inward than a second straight line connecting substantially the center of the first aperture or the light emitting device and an end portion of a second aperture positioned on the light receiver side. It will be described with reference to FIG. 8. FIG. 8 is side cross-sectional views showing configuration examples of light receiving devices 1 according to embodiments of the present technology.

In the embodiment shown in A of FIG. 8, in a side cross-sectional view, a first straight line L1 connecting substantially the center of a first aperture 111 positioned on the opposite side of the light receiver 12 side and the top portion 113 is located more inward than a second straight line L2 connecting substantially the center of the first aperture 111 and an end portion of a second aperture 112 positioned on the light receiver 12 side.

In the embodiment shown in B of FIG. 8, in a side cross-sectional view, a first straight line L1 connecting the light emitting device 2 positioned on the opposite side of the light receiver 12 side and the top portion 113 is located more inward than a second straight line L2 connecting the light emitting device 2 and an end portion of a second aperture 112 positioned on the light receiver 12 side.

Accordingly, the slightly widened emitted light hits the top portion 113 or the like, such that its spread is canceled. As a result, it is possible to prevent the emitted light from the light emitting device from entering the light receiver 12.

It should be noted that although the light transmitting part 11 has the single top portion 113 in the present embodiment, the number of top portions 113 is not limited to one. The light transmitting part 11 may be formed in a stepped-shape with a plurality of steps.

Moreover, as it will be described later in detail, since the light transmitting part 11 is formed in a stepped-shape, it is possible to manufacture a significantly small light receiving device 1 with a length in the width direction of 100 um or less.

The above contents where the light receiving device according to the seventh embodiment of the present technology has been described can be applied to other embodiments of the present technology if there are no particular technical contradictions.

### 8. EIGHTH EMBODIMENT (EXAMPLE 8 OF LIGHT RECEIVING DEVICE)

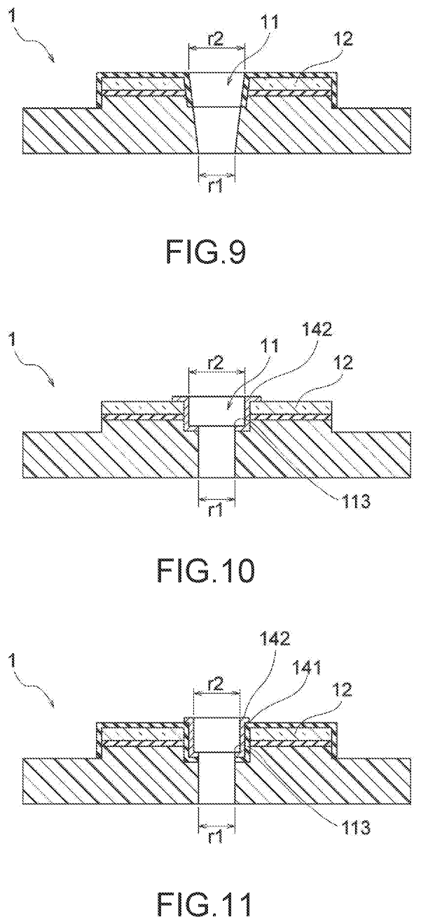

The light transmitting part may be formed so that a diameter on the opposite side of the light receiver side in a side cross-sectional view is smaller than a diameter on the light receiver side. In addition, the light transmitting part may be formed in a taper shape in a side cross-sectional view. It will be described with reference to FIG. 9. FIG. 9 is a side cross-sectional view showing the configuration example of the light receiving device 1 according to the embodiment of the present technology.

As shown in FIG. 9, the light transmitting part 11 is formed so that a diameter r1 on the opposite side of the light receiver 12 side in a side cross-sectional view is smaller than a diameter r2 on the light receiver 12 side. In addition, the light transmitting part 11 is formed in a taper shape in a side cross-sectional view. Accordingly, it is possible to prevent emitted light from the light emitting device (not shown) disposed on the opposite side of the light receiver 12 side from entering the light receiver 12.

It is favorable that the gradient of the light transmitting part 11 is larger than the gradient of the emitted light from the light receiving device (not shown). In particular, it is favorable that the gradient of the light transmitting part 11 is larger than the gradient of the emitted light within a range of 0 to 10 degrees.

The above contents where the light receiving device according to the eighth embodiment of the present technology has been described can be applied to other embodiments of the present technology if there are no particular technical contradictions.

### 9. NINTH EMBODIMENT (EXAMPLE 9 OF LIGHT RECEIVING DEVICE)

The light transmitting part may be formed so that a diameter on the opposite side of the light receiver side in a side cross-sectional view is smaller than a diameter on the light receiver side and the non-sensitive region may include a light shielding film. It will be described with reference to FIG. 10. FIG. 10 is a side cross-sectional view showing the configuration example of the light receiving device 1 according to the embodiment of the present technology.

As shown in FIG. 10, the light transmitting part 11 is formed so that a diameter r1 on the opposite side of the light receiver 12 side in a side cross-sectional view is smaller than a diameter r2 on the light receiver 12 side. The light transmitting part 11 is formed in a stepped-shape and includes the top portion 113.

The non-sensitive region 14 includes a light shielding film 142. As described above, the slightly widened emitted light hits the top portion 113 or the like, such that its spread is canceled. Therefore, the light shielding film 142 only needs to be formed in vicinity of the light receiver 12. Unlike the third and fourth embodiments, the light shielding film 142 does not need to be formed on the opposite side of the light receiver 12 side.

The above contents where the light receiving device according to the ninth embodiment of the present technology has been described can be applied to other embodiments of the present technology if there are no particular technical contradictions.

### 10. TENTH EMBODIMENT (EXAMPLE 10 OF LIGHT RECEIVING DEVICE)

The light transmitting part may be formed so that a diameter on the opposite side of the light receiver side in a side cross-sectional view is smaller than a diameter on the light receiver side and the non-sensitive region may include an insulating film and a light shielding film. It will be described with reference to FIG. 11. FIG. 11 is a side cross-sectional view showing the configuration example of the light receiving device 1 according to the embodiment of the present technology.

As shown in FIG. 11, the light transmitting part 11 is formed so that a diameter r1 on the opposite side of the light receiver 12 side in a side cross-sectional view is smaller than a diameter r2 on the light receiver 12 side. The light transmitting part 11 is formed in a stepped-shape and includes the top portion 113.

The non-sensitive region 14 includes an insulating film 141 and a light shielding film 142. As described above, the slightly widened emitted light hits the top portion 113 or the like, such that its spread is canceled. Therefore, the insulating film 141 and the light shielding film 142 only need to be formed in vicinity of the light receiver 12. Unlike the fourth embodiment, the insulating film 141 and the light shielding film 142 do not need to be formed on the opposite side of the light receiver 12 side.

The above contents where the light receiving device according to the tenth embodiment of the present technology has been described can be applied to other embodiments of the present technology if there are no particular technical contradictions.

### 11. ELEVENTH EMBODIMENT (EXAMPLE 11 OF LIGHT RECEIVING DEVICE)

The light transmitting part may be formed so that a diameter on the opposite side of the light receiver side in a side cross-sectional view is smaller than a diameter on the light receiver side and solder bumps may be formed on the semiconductor substrate. It will be described with reference to FIG. 12. A of FIG. 12 is a plan view showing a configuration example of a light receiving device 1 according to an embodiment of the present technology. B of FIG. 12 is a side cross-sectional view showing the configuration example of the light receiving device 1 according to the embodiment of the present technology.

As shown in B of FIG. 12, the light transmitting part 11 is formed so that a diameter r1 on the opposite side of the light receiver 12 side in a side cross-sectional view is smaller than a diameter r2 on the light receiver 12 side. The light transmitting part 11 is formed in a stepped-shape and includes the top portion 113.

Solder bumps 18 are formed on the semiconductor substrate 13. The solder bumps 18 may be formed on the light receiver side or may be formed on the opposite side of the light receiver side. The solder bumps 18 electrically connect the light receiving device 1 to a circuit board (not shown). The solder bumps 18 can be formed by mounting solder balls on the semiconductor substrate 13 and fusing them. The solder balls are made of, for example, gold-tin (AuSn), tin-silver (SnAg), a tin/silver/copper (SnAgCu) alloy, or the like.

In the manufacturing process for the semiconductor, self-aligning mounting using the surface tension of the solder is performed due to the formed solder bumps 18, such that the positioning can be easily and reliably achieved in the order of um.

It is favorable that two or more solder bumps 18 are formed for the single light receiving device 1. Although the solder bumps 18 are formed at the four corners of the semiconductor substrate 13 in A of FIG. 12, the solder bumps 18 may be formed at any two of the four corners. Accordingly, electrical signals of the anode and the cathode can be acquired.

It is more favorable that three or more solder bumps 18 are formed for the single light receiving device 1. Although the solder bumps 18 are formed at the four corners of the semiconductor substrate 13 in A of FIG. 12, the solder bumps 18 may be formed at any three of the four corners. Accordingly, the positioning in the upper and lower directions and the left and right directions in A of FIG. 12 can be easily and reliably achieved.

The above contents where the light receiving device according to the eleventh embodiment of the present technology has been described can be applied to other embodiments of the present technology if there are no particular technical contradictions.

### 12. TWELFTH EMBODIMENT (EXAMPLE 12 OF LIGHT RECEIVING DEVICE)

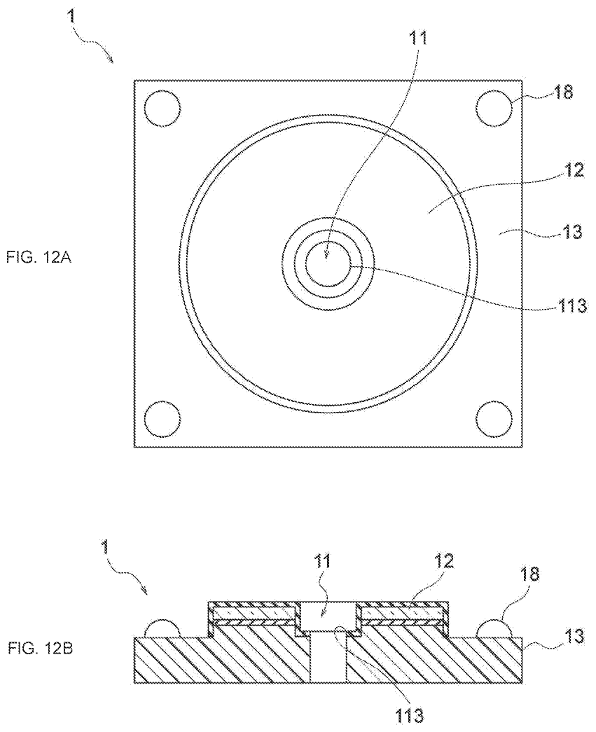

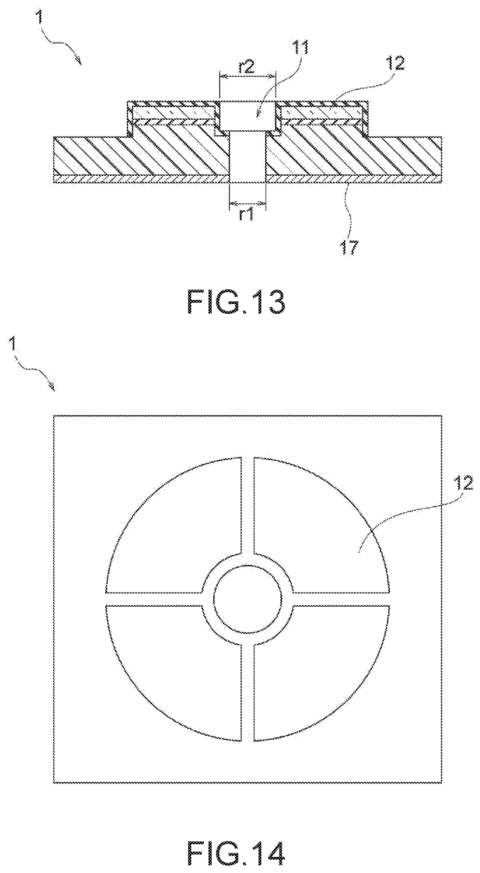

The light transmitting part may be formed so that a diameter on the opposite side of the light receiver side in a side cross-sectional view is smaller than a diameter on the light receiver side and a light shielding layer may be formed on the opposite side of the light receiver side. It will be described with reference to FIG. 13. FIG. 13 is a side cross-sectional view showing the configuration example of the light receiving device 1 according to the embodiment of the present technology.

As shown in FIG. 13, the light transmitting part 11 is formed so that a diameter r1 on the opposite side of the light receiver 12 side in a side cross-sectional view is smaller than a diameter r2 on the light receiver 12 side. The light transmitting part 11 is formed in a stepped-shape and includes the top portion 113.

A light shielding layer 17 is formed on the opposite side of the light receiver 12 side. The light shielding layer 17 includes, for example, metals such as aluminum and gold. The light shielding layer 17 may have a thickness of, for example, 1 μm or less.

In a case where the length of the light receiving device 1 in the direction of the thickness is small, for example, approximately 20 to 30 μm, emitted light with a predetermined wavelength from the light emitting device (not shown) disposed on the opposite side of the light receiver 12 side sometimes passes through the semiconductor substrate 13 and enters the light receiver 12. The formed light shielding layer 17 can prevent the emitted light from the light emitting device from entering the light receiver 12. As a result, it is possible to prevent lowering of the measurement accuracy.

The above contents where the light receiving device according to the twelfth embodiment of the present technology has been described can be applied to other embodiments of the present technology if there are no particular technical contradictions.

### 13. THIRTEENTH EMBODIMENT (EXAMPLE 13 OF LIGHT RECEIVING DEVICE)

The light receiver may include a plurality of regions in a plan view. It will be described with reference to FIG. 14. FIG. 14 is a plan view showing a configuration example of a light receiving device 1 according to an embodiment of the present technology.

As shown in FIG. 14, the light receiver 12 includes a plurality of regions in a plan view. The number of regions is not particularly limited. As shown in the figure, the light receiver 12 may include four or more regions in a plan view. Accordingly, in a case where a target object is tilted and arranged, the optical axis of scattered light or reflected light from the object is different from the optical axis of the emitted light from the light receiving device. In particular, an amount of light received by a particular region of a plurality of regions of the light receiver 12 increases. As a result, a degree of tilt of the object can be known.

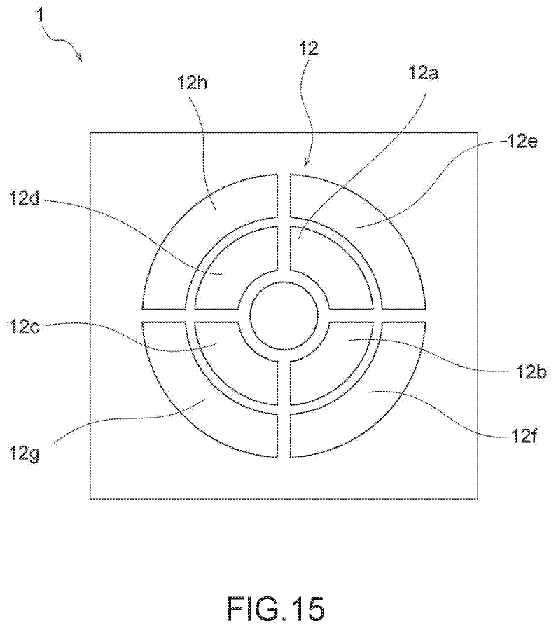

Another example will be described with reference to FIG. 15. FIG. 15 is a plan view showing a configuration example of a light receiving device 1 according to an embodiment of the present technology.

As shown in FIG. 15, the light receiver 12 may include eight or more regions in a plan view. In particular, the light receiver 12 may include four or more regions inside the light receiver 12 and may include four or more regions outside the light receiver 12. Accordingly, a surface state of the target object can be determined. In particular, it is possible to determine whether the surface of the target object is a mirror surface or a rough surface. If it is a mirror surface, an amount of light received by inside regions 12a, 12b, 12c, and 12d of the light receiver 12 can be larger than an amount of light received by outside regions 12e, 12f, 12g, and 12h. If it is a rough surface, the amount of light received by the inside regions 12a, 12b, 12c, and 12d substantially equals the amount of light received by the outside regions 12e, 12f, 12g, and 12h. Whether it is a mirror surface or a rough surface can be determined by comparing the amount of light received by the inside regions 12a, 12b, 12c, and 12d with the amount of light received by the outside regions 12e, 12f, 12g, and 12h.

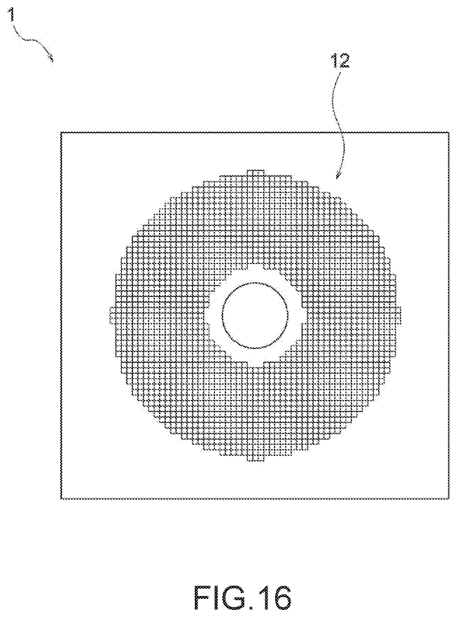

Another example will be described with reference to FIG. 16. FIG. 16 is a plan view showing a configuration example of a light receiving device 1 according to an embodiment of the present technology.

As shown in FIG. 16, the light receiver 12 is disposed so that a plurality of regions are vertically and horizontally arranged like pixels of an image sensor in a plan view. Accordingly, the degree of tilt or surface state of the target object can be determined in detail.

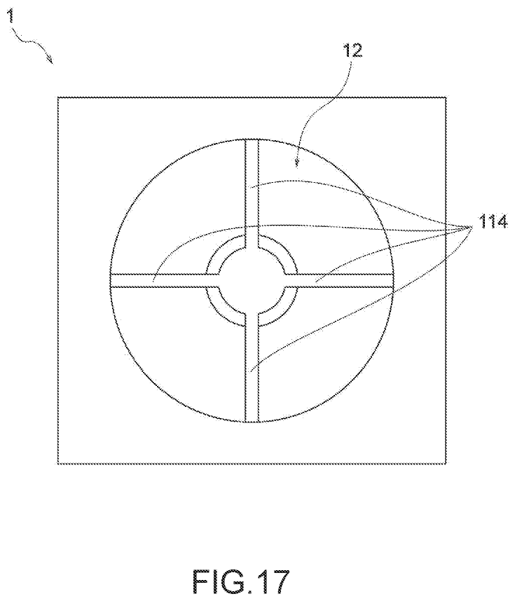

Another example will be described with reference to FIG. 17. FIG. 17 is a plan view showing a configuration example of a light receiving device 1 according to an embodiment of the present technology.

As shown in FIG. 17, the light receiver 12 includes a plurality of regions in a plan view and through-holes 114 are formed between the plurality of regions. The through-holes 114 that constitute the light transmitting part 11 extend in the upper and lower and left and right directions. It should be noted that the number of through-holes 114 and widths, the depths, and the like of the through-holes 114 are not particularly limited.

Since the light receiver 12 includes the plurality of regions, the degree of tilt or surface state of the target object can be known.

The above contents where the light receiving device according to the thirteenth embodiment of the present technology has been described can be applied to other embodiments of the present technology if there are no particular technical contradictions.

### 14. FOURTEENTH EMBODIMENT (EXAMPLE OF DISTANCE MEASUREMENT APPARATUS)

A distance measurement apparatus according to an embodiment of the present technology is a distance measurement apparatus including the light receiving device and a light emitting device that emits the emitted light.

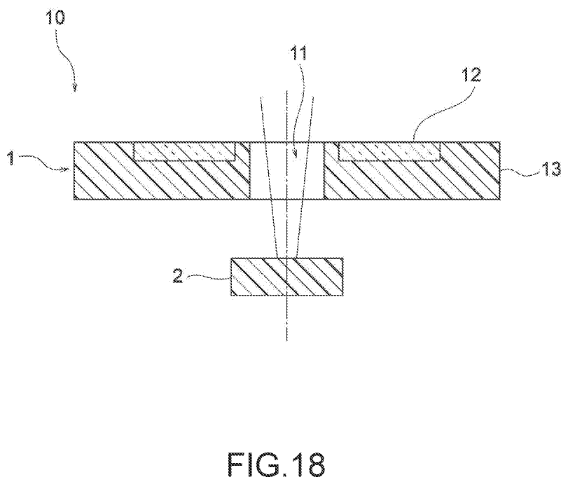

The distance measurement apparatus according to the embodiment of the present technology will be described with reference to FIG. 18. FIG. 18 is a side cross-sectional view showing a configuration example of a distance measurement apparatus 10 according to an embodiment of the present technology.

As shown in FIG. 18, the distance measurement apparatus 10 according to the embodiment of the present technology includes a light receiving device 1 and a light emitting device 2 that emits emitted light.

The light receiving device according to the above-mentioned other embodiment can be applied as the light receiving device 1. For example, a vertical cavity surface emitting laser (VCSEL) or the like can be applied as the light emitting device 2. The light receiving device 1 and the light emitting device 2 can be formed as, for example, a photodetector or the like, integrally stacked on substantially the same axis.

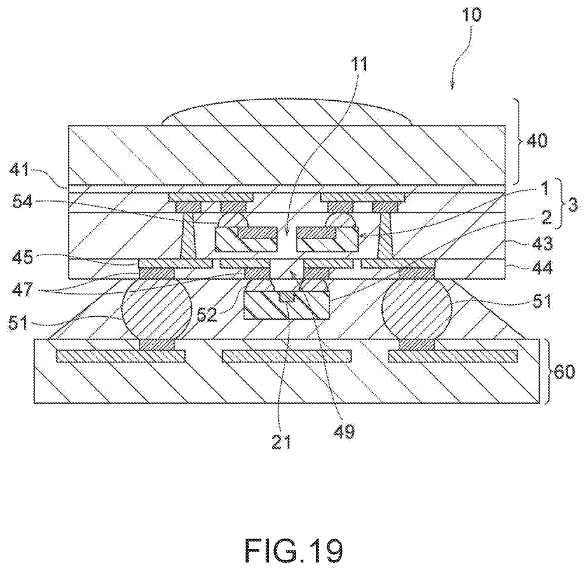

Another example of the distance measurement apparatus will be described with reference to FIG. 19. FIG. 19 is a side cross-sectional view showing a configuration example of a distance measurement apparatus 10 according to an embodiment of the present technology.

As shown in FIG. 19, the distance measurement apparatus 10 includes a light receiving and emitting device 3, a lens substrate 40, and a mother substrate 60. The lens substrate 40 is formed of, for example, quartz or the like. The lens is formed of a resin, an acrylic resin, quartz, or the like. The light receiving and emitting device 3 and the lens substrate 40 are bonded to each other via a light-transmissive adhesive layer 41. The light receiving and emitting device 3 is electrically connected to the mother substrate 60 via bumps 51.

The light receiving device 1 and a wiring layer 45 are electrically connected to each other via bumps 54 and connection holes 42. The wiring layer 45 and the mother substrate 60 are electrically connected to each other via pad portions 47 and the bumps 51.

The light emitting device 2 is electrically connected to the wiring layer 45 via the bumps 52 and the pad portions 47. The wiring layer 45 is electrically connected to the mother substrate 60 via the pad portions 47 and the bumps 51.

An insulating layer 43 allows light to pass therethrough. An insulating layer 44 allows light to pass therethrough because a region of the insulating layer 44, which corresponds to a light emitter 21, is a through-hole 49. The light emitter 21, the through-hole 49, and the light transmitting part 11 are arranged, positioned on an optical axis.

Taking design examples of the respective components, the size of the light receiving device 1 can be 140 μm, the thickness of the light receiving device 1 can be 30 μm, the diameter of the light transmitting part 11 can be Φ30 μm, the size of the light emitting device 2 can be 100 μm, and the thickness of the light emitting device 2 can be 30 μm.

It should be noted that although it is not shown in the figure, the distance measurement apparatus 10 may include a circuit board. The circuit board can include a light emission control unit (laser diode driver (LDD)), a transimpedance amplifier (TIA), a time measurement unit (time to digital converter (TDC)), a distance calculation unit, a serializer, and a deserializer, and the like. The light emission control unit controls light emission of the light emitting device 2. The time measurement unit measures the time between the light emitting device 2 emitting the emitted light and the light receiving device 1 receiving scattered light or reflected light. The distance calculation unit calculates a distance to the object irradiated with light on the basis of the time measured by the time measurement unit.

The above contents where the distance measurement apparatus according to the fourteenth embodiment of the present technology has been described can be applied to other embodiments of the present technology if there are no particular technical contradictions.

### 15. FIFTEENTH EMBODIMENT (EXAMPLE 1 OF LIGHT RECEIVING AND EMITTING DEVICE)

A light receiving and emitting device according to an embodiment of the present technology is a light receiving and emitting device including the light receiving device and a light emitting device that emits the emitted light, in which the light receiving device and the light emitting device are stacked.

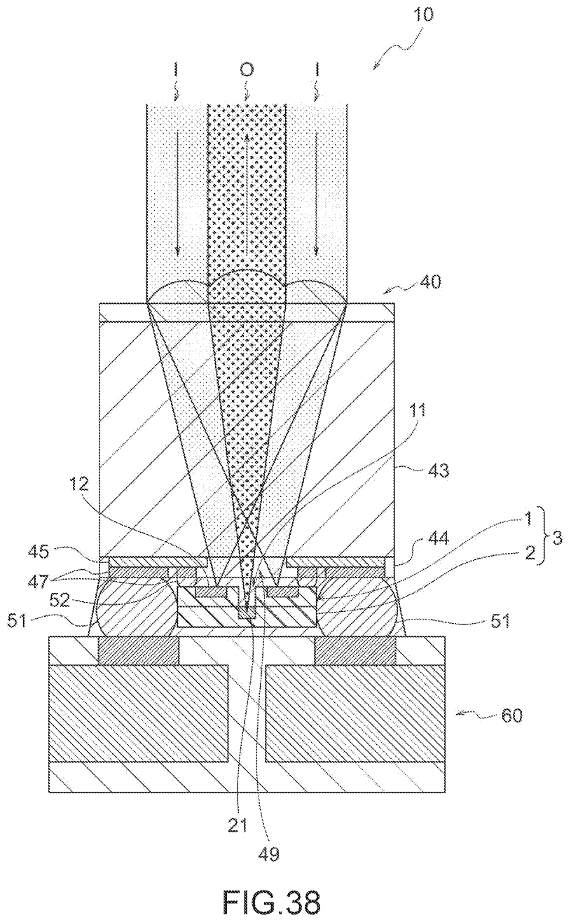

The light receiving and emitting device according to the embodiment of the present technology will be described with reference to FIG. 38. FIG. 38 is a side cross-sectional view showing a configuration example of a light receiving and emitting device 3 according to an embodiment of the present technology. As shown in FIG. 38, stacking the light receiving device 1 and the light emitting device 2 configures the light receiving and emitting device 3. Accordingly, the distance between the light receiving device 1 and the light emitting device 2 decreases. In addition, a wavelength range of incident light I received by the light receiver 12 provided in the light receiving device 1 and a wavelength range of emitted light O emitted by the light emitter 21 provided in the light emitting device 2 are substantially the same. As a result, the light use efficiency is improved. According to a simulation result, it was confirmed that the light use efficiency increased from about 30% to about 57%. In accordance with the present technology, a single axis in the same direction can be realized with substantially the same wavelength. Therefore, the light receiving and emitting device 3 is not limited to the distance measurement module, and the light receiving and emitting device 3 can be provided in any electronic apparatus.

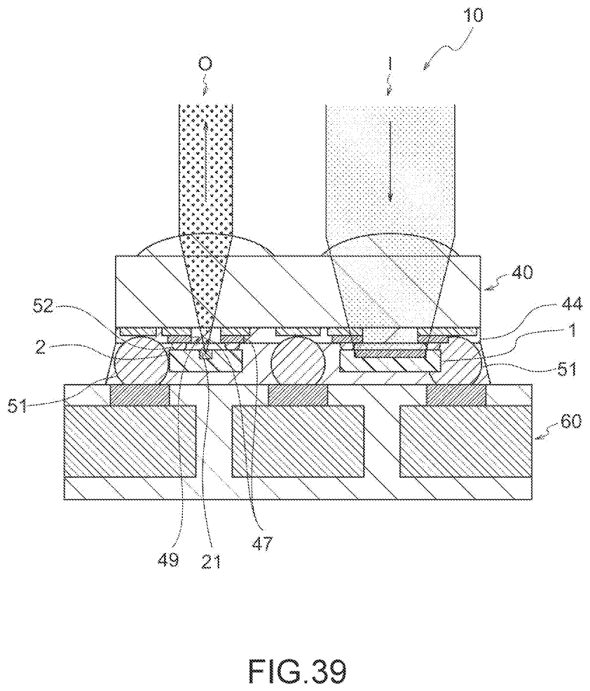

FIG. 39 is a side cross-sectional view showing a configuration example of a light receiving and emitting device according to a comparative example of the present technology. As shown in FIG. 39, in the comparative example, the light receiving device 1 and the light emitting device 2 are arranged side by side on a mother substrate 60. Therefore, the footprint is larger than that of the light receiving and emitting device 3 according to the embodiment of the present technology, which is shown in FIG. 38. In accordance with the present technology, the footprint can be reduced.

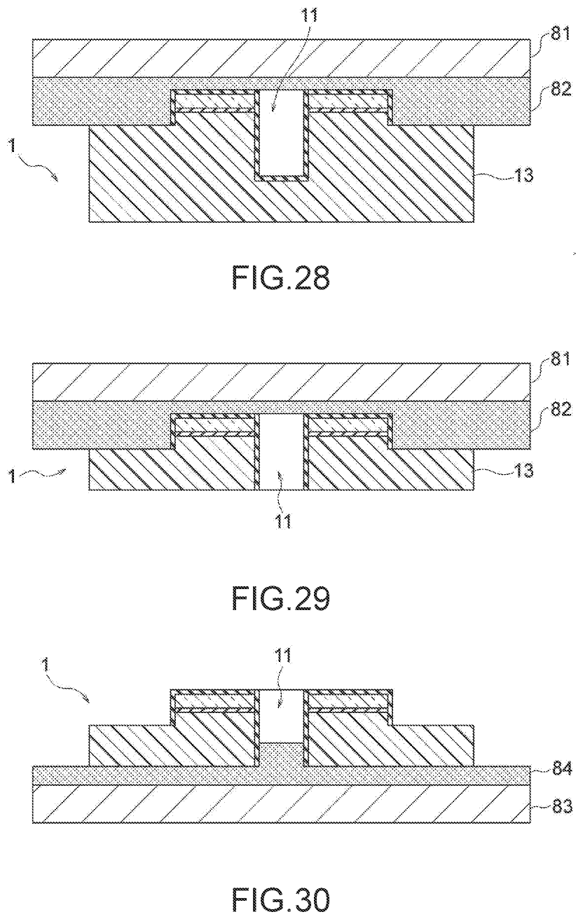

A method of stacking the light receiving device 1 and the light emitting device 2 is not particularly limited. For example, the light receiving device 1 may be temporarily fixed to a temporary fixing substrate 81 as shown in FIG. 28, predetermined machining may be performed on the light receiving device 1, and then the light emitting device 2 may be adhered to the light receiving device 1.

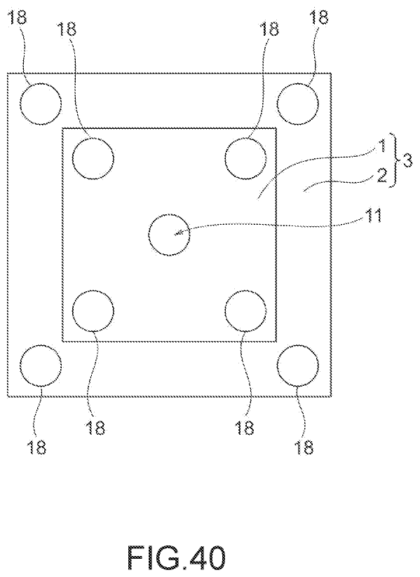

FIG. 40 is a plan view showing a configuration example of a light receiving and emitting device 3 according to an embodiment of the present technology. As shown in FIG. 40, the light receiving device 1 and the light emitting device 2 are stacked. The light transmitting part 11 that transmits emitted light emitted from the light emitting device 2 is formed at substantially the center of the light receiving device 1. Although it is not shown in the figure, the non-sensitive region 14 (see FIG. 1) may be formed in the inner periphery of the light transmitting part 11.

The solder bumps 18 are formed on each of the light receiving device 1 and the light emitting device 2. The solder bumps 18 electrically connect the light receiving device 1 and the light emitting device 2 to each other. In the manufacturing process for the light receiving device 1, self-aligning mounting using the surface tension of the solder is performed due to the formed solder bumps 18, such that the positioning can be easily and reliably achieved in the order of μm.

It should be noted that at least one of the plurality of solder bumps 18 may be a dummy solder bump with no electrical characteristics. This dummy solder bump enables easy and reliable positioning in the order of μm.

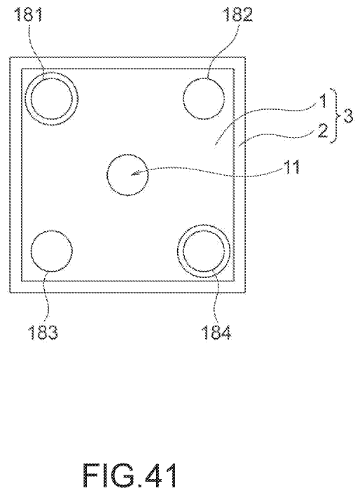

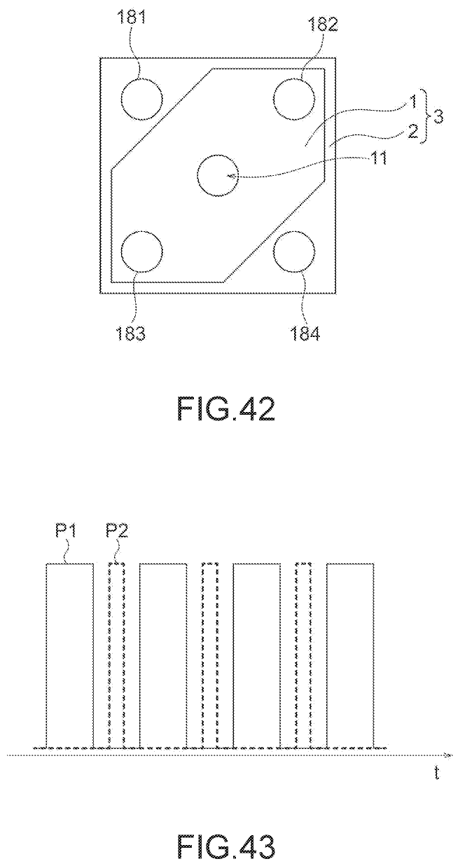

In order to reduce the footprint, it is favorable that a difference between the size of the light receiving device 1 and the size of the light emitting device 2 is small. It will be described with reference to FIGS. 41 and 42. FIGS. 41 and 42 are plan views showing a configuration example of a light receiving and emitting device 3 according to an embodiment of the present technology.

In FIGS. 41 and 42, a first solder bump 181 and a fourth solder bump 184 are formed on the light emitting device 2. A second solder bump 182 and a third solder bump 183 are formed on the light receiving device 1.

In FIG. 41, in order to prevent contact with the light receiving device 1, a clearance is formed at the outer periphery of each of the first solder bump 181 and the fourth solder bump 184. In other words, each of the first solder bump 181 and the fourth solder bump 184 is formed penetrating the light receiving device 1 and a clearance is formed at its outer periphery.

In FIG. 42, in order to prevent contact with the light receiving device 1, the light receiving device 1 is not formed at the outer periphery of each of the first solder bump 181 and the fourth solder bump 184.

At this time, a timing at which the light receiving device 1 senses the incident light and a timing at which the light emitting device 2 emits the emitted light may be different from each other. It will be described with reference to FIG. 43. FIG. 43 is a diagram of assistance in explaining an example of operation timings of a light receiving device 1 and a light emitting device 2 according to an embodiment of the present technology.

In FIG. 43, a first waveform P1 showing the timing at which the light receiving device 1 senses the incident light and a second waveform P2 showing the timing at which the light emitting device 2 emits the emitted light are shown. The horizontal axis indicates a time t. When the first waveform P1 is high, the light receiving device 1 senses the incident light. When the second waveform P2 is high, the light emitting device 2 emits the emitted light. For example, the use of a timing controller or the like can realize this. Since the timing at which the light receiving device 1 senses the incident light and the timing at which the light emitting device 2 emits the emitted light are different from each other, even if the emitted light enters the light receiving device 1 when the emitted light from the light emitting device 2 passes through the light transmitting part 11, the light receiving device 1 does not sense the light that has entered it. Accordingly, it is possible to prevent lowering of the measurement accuracy.

The above contents where the light receiving and emitting device according to the fifteenth embodiment of the present technology has been described can be applied to other embodiments of the present technology if there are no particular technical contradictions.

### 16. SIXTEENTH EMBODIMENT (EXAMPLE 2 OF LIGHT RECEIVING AND EMITTING DEVICE)

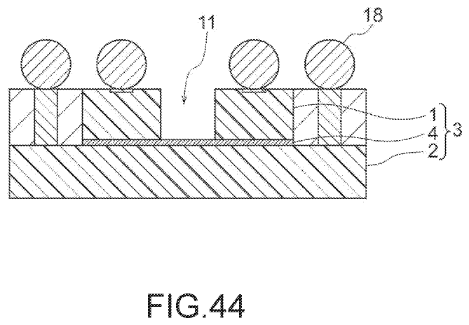

The light receiving and emitting device according to the embodiment of the present technology may further include an electrically conductive layer. It will be described with reference to FIG. 44. FIG. 44 is a side cross-sectional view showing a configuration example of a light receiving and emitting device 3 according to an embodiment of the present technology. As shown in FIG. 44, the light receiving and emitting device 3 further includes an electrically conductive layer 4. The light receiving device 1, the electrically conductive layer 4, and the light emitting device 2 are stacked in the stated order. Accordingly, the crosstalk between signals flowing through a circuit connected to the light receiving device 1 and signals flowing through a circuit connected to the light emitting device 2 can be suppressed.

The electrically conductive layer 4 only needs to be electrically conductive. As the electrically conductive layer 4, for example, an inorganic electrically conductive layer including an inorganic conductive material, an organic electrically conductive layer including an organic conductive material, an organic-inorganic electrically conductive layer including both an inorganic conductive material and an organic conductive material, and the like can be used. An inorganic conductive material and an organic conductive material may be particles.

Examples of the inorganic conductive material include metal and metal oxide. Here, the metal is defined to include semi-metal. Examples of the metal include metals such as aluminum, copper, silver, gold, platinum, palladium, nickel, tin, cobalt, rhodium, iridium, iron, ruthenium, osmium, manganese, molybdenum, tungsten, niobium, tantalum, titanium, bismuth, antimony, and lead and alloys thereof, though not limited thereto. Specific examples of the alloys include stainless steel (stainless used steel (SUS)), an aluminum alloy, a magnesium alloy, and a titanium alloy. Examples of the metal oxide include indium tin oxide (ITO), zinc oxide, indium oxide, antimony-doped tin oxide, fluorine-doped tin oxide, aluminum-doped zinc oxide, gallium-doped zinc oxide, silicon-doped zinc oxide, zinc oxide-tin oxide, indium oxide-tin oxide, and zinc oxide-indium oxide-magnesium oxide, though not limited thereto.

Examples of the organic conductive material include a carbon material and a conductive polymer. Examples of the carbon material include carbon black, carbon fibers, fullerene, graphene, carbon nanotube, carbon microcoil, and nanohorn, though not limited thereto. For example, substituted or non-substituted polyaniline, polypyrrole, polythiophene, and (co-)polymers composed of one or two types selected from among them, or the like can be used as the conductive polymer, though not limited thereto.

The above contents where the light receiving and emitting device according to the sixteenth embodiment of the present technology has been described can be applied to other embodiments of the present technology if there are no particular technical contradictions.

### 17. SEVENTEENTH EMBODIMENT (EXAMPLE OF DISTANCE MEASUREMENT MODULE)

A distance measurement module according to an embodiment of the present technology is a distance measurement module including the above-mentioned distance measurement apparatus. The distance measurement module according to the embodiment of the present technology will be described with reference to FIG. 20. A of FIG. 20 is a perspective view showing a configuration example of a distance measurement module 100 according to an embodiment of the present technology. B of FIG. 20 is a plan view showing the configuration example of the distance measurement module 100 according to the embodiment of the present technology. C of FIG. 20 is a side cross-sectional view showing the configuration example of the distance measurement module 100 according to the embodiment of the present technology. As shown in FIG. 20, a substrate 101 is arranged to configure meridians of the globe (earth). The distance measurement module 100 is configured to have a shape like a lantern which has been slightly vertically pressed. That is, the substrate 101 is arranged to be wrapped around a spherical (substantially spherical) base member which has been slightly vertically pressed. Accordingly, the substantially spherical distance measurement module 100 in which strip regions 102 of the substrate 101 constitute meridians is configured. It should be noted that in order to avoid complication of the figure, the illustration of wires that connect the distance measurement apparatuses 10 to each other is omitted.

The distance measurement apparatuses 10 are arranged on the substrate 101 with lenses oriented outwards. Accordingly, the distance measurement module 100 can be used as, for example, light detection and ranging (LiDAR) scanner or the like.

Assembling of the distance measurement module 100 will be described. The substrate 101 on which the distance measurement apparatuses 10 are arranged is bonded and fixed to a base member with a curved surface, for example, in a convex shape, a spherical shape, or the like. The positioning can be performed by fitting positioning in such a manner that, for example, holes are provided in the substrate 101 and protrusions or the like are provided in the base member. Otherwise, holes may be provided in both the substrate 101 and the base member and these may be positioned and fixed by the use of pins for positioning. Accordingly, the optical axes of the lenses of the distance measurement apparatuses 10 are oriented in directions perpendicular to the curved surface. As a result, each distance measurement apparatus 10 can measure a distance in a direction of interest. Principal specifications of the distance measurement module 100, such as a distance measurement angle and a resolution, can be freely set by varying mounting positions, pitches, and the like of the distance measurement apparatuses 10. For example, a high resolution can be set in one direction and a low resolution can be set in another direction.

It should be noted that for example a distance measurement module 100 having a high resolution which is a resolution of 1° or less requires many distance measurement apparatuses 10. For example, in a case of distance measurement in 360 degree directions with a resolution of 0.1° (vertically and horizontally), about 6,500,000 (=3,600×1,800) distance measurement apparatuses 10 are required. In a case where such a high resolution is required, it is effective to make the base member rotatable in order to cut the manufacture costs. For example, distance measurement apparatuses 10 are mounted at every 10° (36 lines) in a H (Horizontal) direction and at every 3.6° (50 apparatuses) in a V (Vertical) direction and the mounting positions are offset by each 0.1° and they are made to perform rotational scanning. Accordingly, a resolution of 0.1° can be realized by only 1,800 (=36×50) distance measurement apparatuses 10. For reference, at this time, 3,600 times of (=360°/0.1°) distance measurement are performed for a single rotation. Provided that 0.5 millisecond is required for a single measurement, such a measurement can be performed if the rotation is performed for 1.8 seconds (=0.5 millisecond×3,600 times) for a single rotation.

Although it is not shown in the figure, the distance measurement module 100 may employ an embodiment where the substrate 101 is mounted on an umbrella frame-shaped base member. For example, distance measurement apparatuses 10 are mounted at every 90° (4 lines) in the H direction and at every 6° (30 apparatuses) in the V direction and the mounting positions are offset by each 1.5° and they are made to perform rotational scanning. If they are rotated by varying the angle of the frame by 0.1° for each rotation at that time, the number of distance measurement apparatuses 10 can be reduced to 120 (4×30) apparatuses. For reference, at this time, 3,600 times of distance measurement are performed for a single rotation. Provided that 0.5 millisecond is required for a single measurement, omnidirectional scanning is completed by 15 rotations if the rotation is performed for 1.8 seconds (=0.5 millisecond×3,600 times) for a single rotation.

It should be noted that the shape of the distance measurement module 100 is not limited to this lantern-type. The shape of the distance measurement module 100 may be, for example, a one straight line shape, a radial shape, a spiral shape, a zigzag shape, or the like.

The above contents where the distance measurement module according to the seventeenth embodiment of the present technology has been described can be applied to other embodiments of the present technology if there are no particular technical contradictions.

### 18. EIGHTEENTH EMBODIMENT (EXAMPLE OF ELECTRONIC APPARATUS)

An electronic apparatus according to an embodiment of the present technology is an electronic apparatus including the above-mentioned distance measurement apparatus or the above-mentioned light receiving and emitting device.

The electronic apparatus according to the embodiment of the present technology will be described with reference to FIG. 21. FIG. 21 is a perspective view showing a configuration example of an electronic apparatus 200 according to an embodiment of the present technology.

As shown in FIG. 21, distance measurement modules 100 each obtained by bonding a substrate 201 with a plurality of distance measurement apparatuses 10 arranged in a grid form to a flat surface or a gentle curved surface are built in, for example, bumper, body, and the like of a car (electronic apparatus) 200. Accordingly, the car body itself can be configured as a sensor. By bonding a linear substrate to an axial base member and rotating it, the distance measurement module 100 becomes an elongated high-definition linear sensor-type. By bonding the distance measurement modules 100 to a windshield wiper, a steering wheel, a wheel, and the like of the car, they can be configured to perform scanning by making use of the movable structures of the car main body itself. If the distance measurement modules 100 are arranged with a low-density on the ceiling of the vehicle, they can also be used as sensors for detecting passenger motion and the like of a large-sized transit bus. If the distance measurement modules 100 with the substrate 201 made transparent is bonded to front, rear, and side glasses, they can also be used as distance measurement sensors having transmittance. By employing a soft one as the base member, a freely deformable distance measurement module 100 can also be realized. As a matter of course, if only one distance measurement apparatus 10 is used, it also functions as a significantly cheaper, single-point distance measurement module 100.

Otherwise, the distance measurement apparatus 10 can be provided in an electronic apparatus, for example, a digital camera, a smartphone, a tablet, or the like.

In this manner, the technology of the present disclosure has a significantly high degree of freedom in design. With a distance measurement apparatus 10 which is a base, it is possible to cope with requirements from various customers at low costs.

The above contents where the electronic apparatus according to the eighteenth embodiment of the present technology has been described can be applied to other embodiments of the present technology if there are no particular technical contradictions.

### 19. NINETEENTH EMBODIMENT (EXAMPLE OF MANUFACTURING METHOD FOR LIGHT RECEIVING DEVICE)

### (1) Comparative Example 1

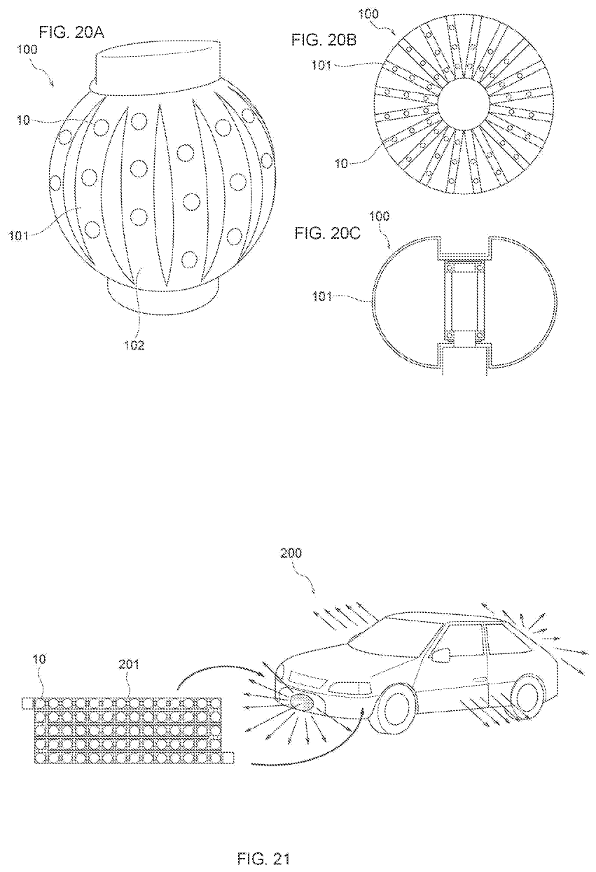

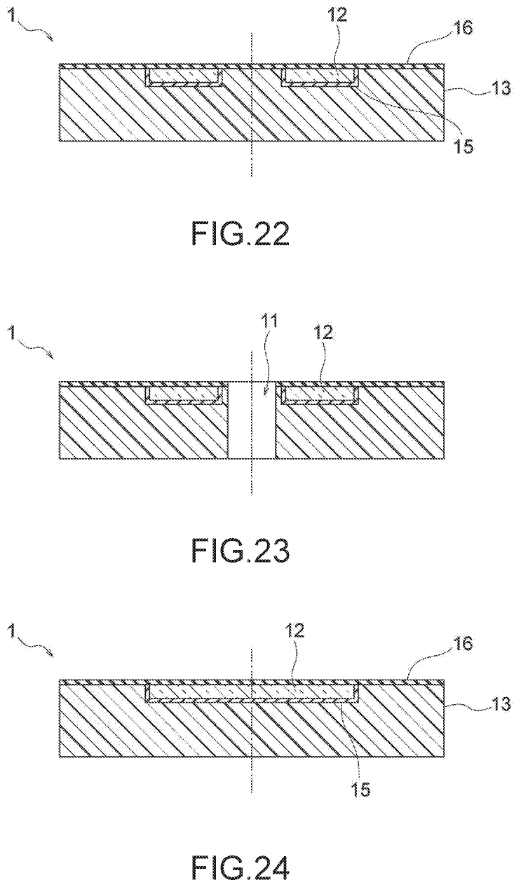

As a comparative example of the present technology, a manufacturing method for a light receiving device which is generally performed will be described with reference to FIGS. 22 and 23. FIGS. 22 and 23 are side cross-sectional views showing a configuration example of a light receiving device 1 according to the comparative example of the present technology.

As shown in FIG. 22, in the light receiving device 1, the light receiver 12, the first insulating layer 15, and the second insulating layer 16 are formed on the semiconductor substrate 13. The light receiver 12 is formed in a ring shape. It should be noted that also in the configuration example in which the first insulating layer 15 is not formed, the following manufacturing method is applied.

The thickness of the light receiver 12 can be, for example, 5 μm or less, the thickness of the first insulating layer 15 can be, for example, 5 μm or less, and the thickness of the second insulating layer 16 can be, for example, 1 μm or less.

As shown in FIG. 23, a through-hole is formed as the light transmitting part 11 at substantially the center portion of the light receiver 12 formed in a ring shape by dry etching or the like.

### (2) Comparative Example 2

Here, manufacture for a light receiving device having a size as small as possible in a case where the conventional technology is used will be considered.

The emitted light from the light receiving device generally has a diameter of about Φ20 μm and a beam angle (2θ1/2) of about 15 degrees. It should be noted that in a case where the emitted light is made parallel light through a lens or the like, the beam angle is closer to zero.

On the other hand, in a case where the light receiving device is applied to a ToF sensor or the like, if the surface of the target object is a mirror surface, reflected light of object light is closer to Gaussian distribution and the power density near the center of the optical axis increases. Therefore, it is necessary to make the light receiving device and the light receiver as small as possible for increasing the light reception sensitivity and the response speed. In a case where the light receiver temporarily has a larger diameter, the parasitic capacitance increases, and it becomes difficult for the light receiver to react pulses with a short pulse width in units of picoseconds or nanoseconds.

In order to make the diameter of the light receiver as small as possible, it is desirable to reduce the diameter of the light transmitting part to, for example, about Φ50 μm or less.

However, in a case where the diameter of the light receiver is made as small as possible, there is a problem in that it becomes difficult to manufacture it in consideration of variations in the thickness and position of the light receiver, variations in the thickness and position of the first insulating layer, a variation in the position of the light transmitting part, yield in mass production, or the like.

In view of this, a manufacturing method for solving this problem will be described with reference to FIGS. 24 to 26. FIGS. 24 to 26 are side cross-sectional views showing a configuration example of a light receiving device 1 according to a comparative example of the present technology.

As shown in FIG. 24, in the light receiving device 1, the light receiver 12, the first insulating layer 15, and the second insulating layer 16 are formed on the semiconductor substrate 13. The light receiver 12 is formed in a circular shape.

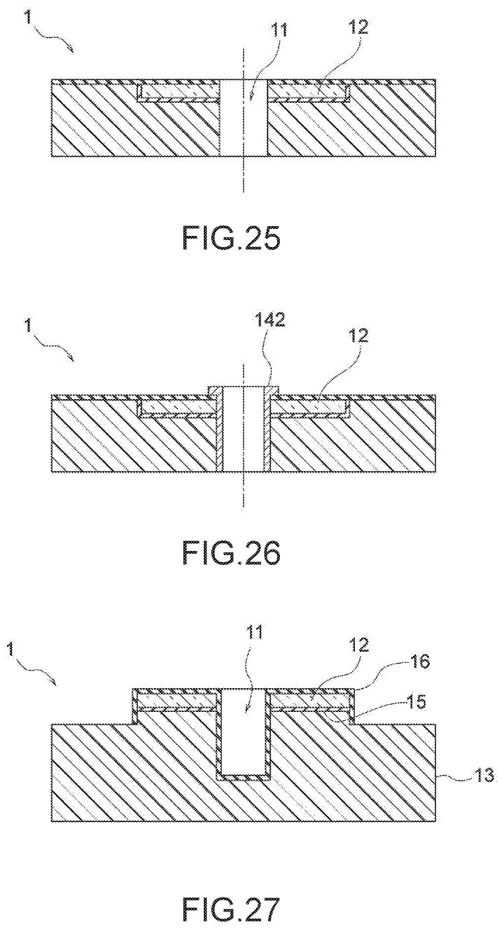

As shown in FIG. 25, a through-hole is formed as the light transmitting part 11 at substantially the center portion of the light receiver 12 formed in a circular shape by dry etching or the like.

Next, as shown in FIG. 26, the light shielding film 142 is formed to conform to the inner wall of the light transmitting part 11. Accordingly, it is possible to prevent the emitted light from the light emitting device from entering the light receiver 12.

In order to reliably form the light shielding film 142, it is favorable that the light shielding film 142 is formed to be larger than the diameter of the light transmitting part 11 in the upper surface of the light receiving device 1. Accordingly, even if the position when the light shielding film 142 is formed changes, the light shielding film 142 can be reliably formed.

However, since the light shielding film 142 is formed to be larger than the diameter of the light transmitting part 11, there arises a problem in that the area of the light receiver 12 decreases and the light receiver 12 cannot be efficiently used. Moreover, there also arises a problem in that the parasitic capacitance increases and the response speed lowers. In addition, in a case where an insulating layer for reducing the leak current between layers as a front end is provided, there also arises a problem in that the number of processes increases and the manufacture costs increase.

### (3) Comparative Example 3

In view of this, a manufacturing method for solving this problem will be described with reference to FIGS. 27 to 30. FIGS. 27 to 30 are side cross-sectional views showing a configuration example of a light receiving device 1 according to a comparative example of the present technology.

As shown in FIG. 27, in the light receiving device 1, the light receiver 12, the first insulating layer 15, and the second insulating layer 16 are formed on the semiconductor substrate 13. The light receiver 12 is formed in a circular shape.

A hole is formed as the light transmitting part 11 at substantially the center portion of the light receiver 12 formed in a ring shape by dry etching or the like. It is favorable that the depth of the hole is larger than the thickness of the light receiving device 1 when it is completed.

Next, as shown in FIG. 28, the upper surface of the light receiving device 1 is temporarily fixed through the temporary fixing substrate 81 and a temporary fixing adhesive 82. For example, a glass, a sapphire, or the like can be used for the temporary fixing substrate 81.

Next, as shown in FIG. 29, the semiconductor substrate 13 is ground to be thinner. At this time, there arises a problem in that the waste material generated from the grinding process enters a hole 11. When the waste material enters the hole 11, the emitted light from the light receiving device cannot passes therethrough. Therefore, this light receiving device 1 becomes useless and the manufacture costs increase.

Moreover, there also arises a problem in that the semiconductor substrate 13 is broken from the hole 11 when the semiconductor substrate 13 is ground.

Next, as shown in FIG. 30, the lower surface of the light receiving device 1 is permanently fixed through a permanent fixing substrate 83 and a permanent fixing adhesive 84. The temporary fixing substrate 81 and the permanent fixing substrate 83 apply pressure on the light receiving device 1 while sandwiching it. Then, the temporary fixing substrate 81 and the temporary fixing adhesive 82 are removed by liquid chemicals, heat, or the like.

When the temporary fixing substrate 81 and the permanent fixing substrate 83 apply pressure on the light receiving device 1 while sandwiching it, the permanent fixing adhesive 84 may enter the hole 11. It is difficult to remove the permanent fixing adhesive 84 that has entered it. In a case of removing the permanent fixing adhesive 84 by adding impact from the upper surface by dry etching or the like, the impact may damage the light receiving device 1. There arises a problem in that if the permanent fixing adhesive 84 remains inside the hole 11, it diffuse-reflects the emitted light from the light receiving device.

### (4) Example of Present Technology

A manufacturing method for a light receiving device according to an embodiment of the present technology is a manufacturing method including stacking a light receiver on one surface of a semiconductor substrate, etching a side on which the light receiver is disposed into a ring shape, fixing the semiconductor substrate to a permanent fixing substrate, etching an outer periphery and substantially a center portion of the light receiver, and removing the semiconductor substrate from the permanent fixing substrate by laser lift off.

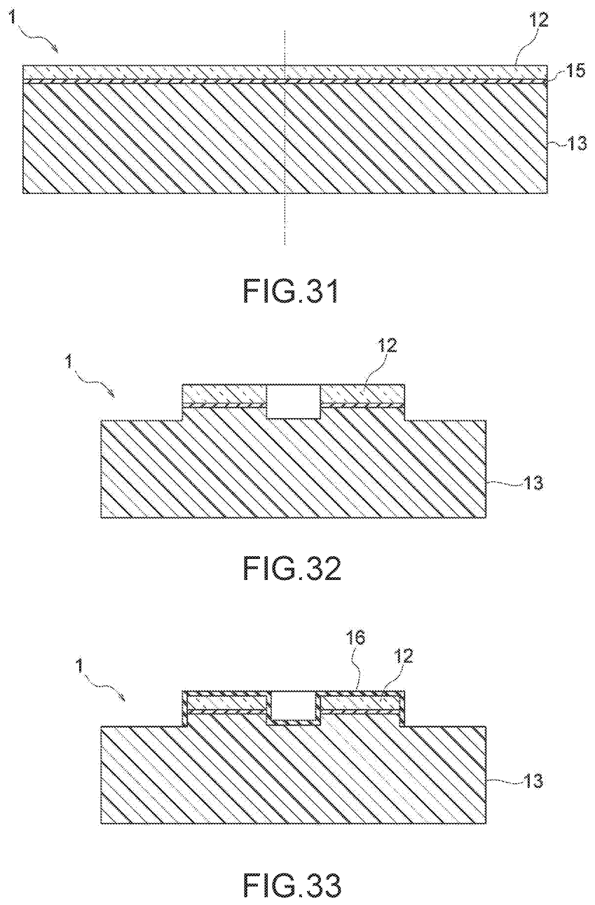

An example of the present technology will be described with reference to FIGS. 31 to 37. FIGS. 31 to 37 are side cross-sectional views showing a configuration example of a light receiving device 1 according to an embodiment of the present technology.

First of all, as shown in FIG. 31, the light receiver 12 and the first insulating layer 15 are stacked in the stated order and disposed on one surface of the semiconductor substrate 13.

Next, as shown in FIG. 32, the side on which the light receiver 12 is disposed is etched into a ring shape. The outer diameter of the light receiver 12 can be, for example, Φ100 μm or less, favorably Φ80 μm or less, and more favorably Φ60 μm or less. The inner diameter of the light receiver 12 can be, for example, Φ50 μm or less, favorably Φ45 μm or less, and more favorably Φ40 μm or less. The etching depth can be, for example, 10 to 15 μm.

Although it is not shown in the figure, the light receiver 12 is disposed on the semiconductor substrate 13, for example, in an array form at pitches of 125 μm.

Next, as shown in FIG. 33, the second insulating layer 16 is formed on the upper surface of the light receiving device 1. The thickness of the second insulating layer 16 may be, for example, 1 μm or less on the inner wall of the light receiver 12.

Next, the semiconductor substrate 13 is ground to be thinner. The thickness of the semiconductor substrate 13 can be, for example, 100 μm or less, favorably 60 μm or less, and more favorably 30 μm or less.

It should be noted that the light shielding film (not shown) may be formed on the inner wall of the light receiver 12. The thickness of the light shielding film may be, for example, 1 μm or less on the inner wall of the light receiver 12.

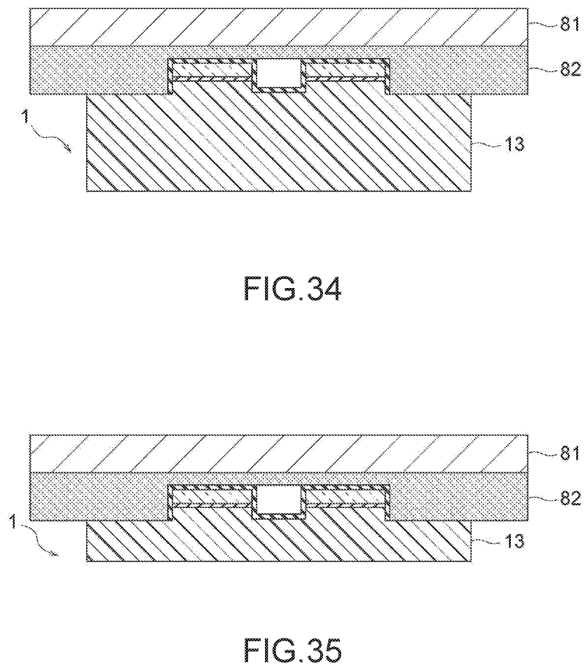

Next, as shown in FIG. 34, the upper surface of the light receiving device 1 is fixed to the temporary fixing substrate 81 via the temporary fixing adhesive 82. For example, a glass, a sapphire, or the like can be used for the temporary fixing substrate 81. The thickness of the temporary fixing substrate 81 can be, for example, about 500 μm.

Next, as shown in FIG. 35, the semiconductor substrate 13 is ground to be thinner. The thickness of the semiconductor substrate 13 can be, for example, about 30 μm.

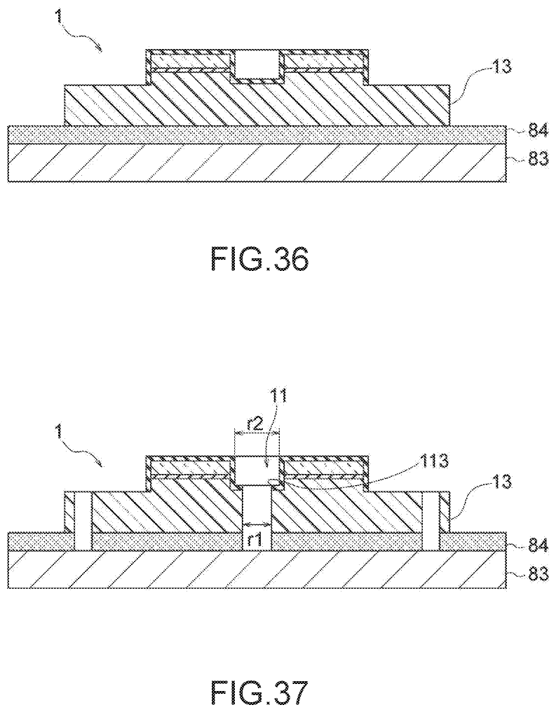

Next, as shown in FIG. 36, the semiconductor substrate 13 is fixed to the permanent fixing substrate 83 via the permanent fixing adhesive 84. Then, the temporary fixing substrate 81 and the temporary fixing adhesive 82 are removed by liquid chemicals, heat, or the like.

For example, a glass, a sapphire, or the like can be used for the permanent fixing substrate 83. The thickness of the permanent fixing substrate 83 can be, for example, about 500 μm. The thickness of the permanent fixing adhesive 84 can be, for example, about 1 μm.

Next, as shown in FIG. 37, the light receiving device 1 disposed in an array form is separated by etching the outer periphery of the light receiver 12. The width when it is separated can be, for example, about 20 μm.

Moreover, a hole is formed as the light transmitting part 11 by etching substantially the center portion of the light receiver 12 as in the separation. The diameter of the hole can be, for example, about Φ30 μm.

The hole that is the light transmitting part 11 is formed so that a diameter r1 on the opposite side of the light receiver 12 side in a side cross-sectional view is smaller than a diameter r2 on the light receiver 12 side. The hole is formed in a stepped-shape in a side cross-sectional view and has a top portion 113.

At last, the light receiving device 1 is removed from the permanent fixing substrate 83. In a case of sorting small-size light receiving devices one by one by using a generally-used pick and place process, there are problems in that the cycle time is long and high-accuracy work is required because of their small size. In addition, in the present technology, it is impossible to use a generally-used vacuum suction head because the through-hole is formed at substantially the center portion of the light receiving device 1.

In view of this, in the present technology, the light receiving device 1 is removed from the permanent fixing substrate 83 by laser lift off. The laser lift off is a technology that removes the light receiving device 1 by emitting pulsed, high-density UV laser light to the permanent fixing substrate 83. For example, when laser light with a diameter of the optical axis of 100 μm is emitted to the permanent fixing substrate 83, the laser light passes through the permanent fixing substrate 83 and only the light receiving device 1 as a target is radiated with it. Only the radiated light receiving device 1 is removed from the permanent fixing substrate 83. Accordingly, for example, the light receiving device 1 with a small size of 100 μm is manufactured without being damaged.

The above contents where the manufacturing method for a light receiving device according to the nineteenth embodiment of the present technology has been described can be applied to other embodiments of the present technology if there are no particular technical contradictions.

It should be noted that embodiments according to the present technology are not limited to the above-mentioned embodiments and various modifications can be made without departing from the gist of the present technology.

Moreover, the present technology can also take the following configurations.
[1] A light receiving device, including:
   a light transmitting part that transmits emitted light emitted from a light emitting device;
   a light receiver that receives incident light from outside; and
   a semiconductor substrate, in which
   a non-sensitive region that does not sense light is formed between the light transmitting part and the light receiver.
[2] The light receiving device according to [1], in which
   the non-sensitive region includes an insulating film.
[3] The light receiving device according to [1] or [2], in which
   the non-sensitive region includes a light shielding film.
[4] The light receiving device according to any one of [1] to [3], in which
   the non-sensitive region includes an insulating film and a light shielding film.
[5] The light receiving device according to any one of [1] to [4], in which
   a solder bump is formed on the semiconductor substrate.
[6] The light receiving device according to any one of [1] to [5], in which
   a light shielding layer is formed on an opposite side of the light receiver side.
[7] The light receiving device according to any one of [1] to [6], in which
   the light transmitting part is formed so that a diameter on an opposite side of the light receiver side in a side cross-sectional view is smaller than a diameter on the light receiver side.
[8] The light receiving device according to any one of [1] to [7], in which
   the light transmitting part is formed in a stepped-shape in a side cross-sectional view and has a top portion.
[9] The light receiving device according to [8], in which
   in a side cross-sectional view, a first straight line connecting substantially a center of a first aperture positioned on an opposite side of the light receiver side or the light emitting device and the top portion is positioned more inward than a second straight line connecting substantially a center of the first aperture or the light emitting device and an end portion of a second aperture positioned on the light receiver side.
[10] The light receiving device according to any one of [1] to [9], in which
   the light transmitting part is formed in a taper shape in a side cross-sectional view.
[11] The light receiving device according to any one of [1] to [10], in which
   the light transmitting part is formed of a transparent material which is transparent or translucent.
[12] The light receiving device according to any one of [1] to [11], in which
   the light receiver is formed in a ring shape in a plan view.
[13] The light receiving device according to any one of [1] to [12], in which
   the light receiver includes a plurality of regions in a plan view.
[14] The light receiving device according to any one of [1] to [13], in which
   the light receiver includes four or more regions in a plan view.
[15] The light receiving device according to any one of [1] to [14], in which
   the light receiver includes eight or more regions in a plan view.
[16] The light receiving device according to any one of [1] to [15], in which
   the light receiver is disposed so that a plurality of regions is vertically and horizontally arranged in a plan view.
[17] A distance measurement apparatus, including:
   the light receiving device according to any one of [1] to [16]; and
   a light emitting device that emits the emitted light.
[18] A light receiving and emitting device, including:
   the light receiving device according to any one of [1] to [16]; and
   a light emitting device that emits the emitted light, in which
   the light receiving device and the light emitting device are stacked.
[19] The light receiving and emitting device according to [18], in which
   a wavelength range of incident light received by the light receiving device and a wavelength range of emitted light emitted by the light emitting device are substantially the same.
[20] The light receiving and emitting device according to or [19], in which
   a timing at which the light receiving device senses incident light and a timing at which the light emitting device emits emitted light are different from each other.
[21] The light receiving and emitting device according to any one of [18] to [20], further including
   an electrically conductive layer, in which
   the light receiving device, the electrically conductive layer, and the light emitting device are stacked in the stated order.
[22] A distance measurement module, including
   the distance measurement apparatus according to [17].
[23] An electronic apparatus, including
   the distance measurement apparatus according to [17].
[24] An electronic apparatus, including
   the light receiving and emitting device according to any one of [18] to [21].
[25] A manufacturing method for a light receiving device, including:
   stacking a light receiver on one surface of a semiconductor substrate;
   etching a side on which the light receiver is disposed into a ring shape;
   fixing the semiconductor substrate to a permanent fixing substrate;
   etching an outer periphery and substantially a center portion of the light receiver; and
   removing the semiconductor substrate from the permanent fixing substrate by laser lift off.

### REFERENCE SIGNS LIST

1 light receiving device
11 light transmitting part
111 first aperture
112 second aperture
113 top portion
114 through-hole
12 light receiver
12a, 12b, 12c, 12d inside region of light receiver
12e, 12f, 12g, 12h outside region of light receiver
13 semiconductor substrate
14 non-sensitive region
141 insulating film
142 light shielding film
15 first insulating layer
16 second insulating layer
17 light shielding layer
2 light emitting device
21 light emitter
3 light receiving and emitting device
4 electrically conductive layer
10 distance measurement apparatus
18 solder bumps
100 distance measurement module
200 electronic apparatus
81 temporary fixing substrate
82 temporary fixing adhesive
83 permanent fixing substrate
84 permanent fixing adhesive

1. A light receiving device, comprising:
a light transmitting part that transmits emitted light emitted from a light emitting device;
a light receiver that receives incident light from outside; and
a semiconductor substrate, wherein
a non-sensitive region that does not sense light is formed between the light transmitting part and the light receiver.

2. The light receiving device according to claim 1, wherein
the non-sensitive region includes an insulating film.

3. The light receiving device according to claim 1, wherein
the non-sensitive region includes a light shielding film.

4. The light receiving device according to claim 1, wherein
the non-sensitive region includes an insulating film and a light shielding film.

5. The light receiving device according to claim 1, wherein
a solder bump is formed on the semiconductor substrate.

6. The light receiving device according to claim 1, wherein
a light shielding layer is formed on an opposite side of the light receiver side.

7. The light receiving device according to claim 1, wherein
the light transmitting part is formed so that a diameter on an opposite side of the light receiver side in a side cross-sectional view is smaller than a diameter on the light receiver side.

8. The light receiving device according to claim 1, wherein
the light transmitting part is formed in a stepped-shape in a side cross-sectional view and has a top portion.

9. The light receiving device according to claim 8, wherein
in a side cross-sectional view, a first straight line connecting substantially a center of a first aperture positioned on an opposite side of the light receiver side or the light emitting device and the top portion is positioned more inward than a second straight line connecting substantially a center of the first aperture or the light emitting device and an end portion of a second aperture positioned on the light receiver side.

10. The light receiving device according to claim 1, wherein
the light transmitting part is formed in a taper shape in a side cross-sectional view.

11. The light receiving device according to claim 1, wherein
the light transmitting part is formed of a transparent material which is transparent or translucent.

12. The light receiving device according to claim 1, wherein
the light receiver is formed in a ring shape in a plan view.

13. The light receiving device according to claim 1, wherein
the light receiver includes a plurality of regions in a plan view.

14. The light receiving device according to claim 1, wherein
the light receiver includes four or more regions in a plan view.

15. The light receiving device according to claim 1, wherein
the light receiver includes eight or more regions in a plan view.

16. The light receiving device according to claim 1, wherein
the light receiver is disposed so that a plurality of regions is vertically and horizontally arranged in a plan view.

17. A distance measurement apparatus, comprising:
the light receiving device according to claim 1; and
a light emitting device that emits the emitted light.

18. A distance measurement module, comprising
the distance measurement apparatus according to claim 17.

19. An electronic apparatus, comprising the distance measurement apparatus according to claim 17.

20. A manufacturing method for a light receiving device, comprising:
stacking a light receiver on one surface of a semiconductor substrate;
etching a side on which the light receiver is disposed into a ring shape;
fixing the semiconductor substrate to a permanent fixing substrate;
etching an outer periphery and substantially a center portion of the light receiver; and
removing the semiconductor substrate from the permanent fixing substrate by laser lift off.
